(19) United States
(12) Patent Application Publication
(10) Pub. No.: US 2026/0354225 A1
(43) Pub. Date: Nov. 5, 2026

(54) METHODS AND APPARATUS TO IMPROVE INTERCONNECT BRIDGE PITCH SCALING AND OVERLAY ALIGNMENT

(71) Applicants: Jeremy David Ecton, Gilbert, AZ (US); Yonggang Li, Chandler, AZ (US); Matthew Lee Tingey, Mesa, AZ (US); Dilan Seneviratne, Phoenix, AZ (US); Changhua Liu, Chandler, AZ (US); Manohar Shenoy Konchady, Chandler, AZ (US); Srinivas Venkata Ramanuja Pietambaram, Chandler, AZ (US); Tarek Adly Ibrahim, Mesa, AZ (US); Bainye Francoise Angoua, Phoenix, AZ (US); Jefferson Coker Kaplan, Gilbert, AZ (US); Hongxia Feng, Chandler, AZ (US); Gang Duan, Chandler, AZ (US); Jung Kyu Han, Chandler, AZ (US); Joshua James Stacey, Chandler, AZ (US); Thomas Stanley Heaton, Gilbert, AZ (US); Ali Lehaf, Phoenix, AZ (US); Hiroki Tanaka, Gilbert, AZ (US); Mohammad Mamunur Rahman, Chandler, AZ (US); Ala Omer, Mesa, AZ (US); Whitney Michael Bryks, Chandler, AZ (US); Haobo Chen, Chandler, AZ (US); Yeasir Arafat, Gilbert, AZ (US); Jonathan Gabriel Glenn, Phoenix, AZ (US); Bohan Shan, Chandler, AZ (US); Aaditya Anand Candadai, Chandler, AZ (US); Jose Fernando Waimin Almendares, Gilbert, AZ (US); Max Mohammadi Ghaleni, Phoenix, AZ (US); Ryan Joseph Carrazzone, Chandler, AZ (US); Ching-Wei Lee, Chandler, AZ (US); Chase Everett Ferrone, Gilbert, AZ (US); Seyyed Yahya Mousavi, Chandler, AZ (US)

(72) Inventors: Jeremy David Ecton, Gilbert, AZ (US); Yonggang Li, Chandler, AZ (US); Matthew Lee Tingey, Mesa, AZ (US); Dilan Seneviratne, Phoenix, AZ (US); Changhua Liu, Chandler, AZ (US); Manohar Shenoy Konchady, Chandler, AZ (US); Srinivas Venkata Ramanuja Pietambaram, Chandler, AZ (US); Tarek Adly Ibrahim, Mesa, AZ (US); Bainye Francoise Angoua, Phoenix, AZ (US); Jefferson Coker Kaplan, Gilbert, AZ (US); Hongxia Feng, Chandler, AZ (US); Gang Duan, Chandler, AZ (US); Jung Kyu Han, Chandler, AZ (US); Joshua James Stacey, Chandler, AZ (US); Thomas Stanley Heaton, Gilbert, AZ (US); Ali Lehaf, Phoenix, AZ (US); Hiroki Tanaka, Gilbert, AZ (US); Mohammad Mamunur Rahman, Chandler, AZ (US); Ala Omer, Mesa, AZ (US); Whitney Michael Bryks, Chandler, AZ (US); Haobo Chen, Chandler, AZ (US); Yeasir Arafat, Gilbert, AZ (US); Jonathan Gabriel Glenn, Phoenix, AZ (US); Bohan Shan, Chandler, AZ (US); Aaditya Anand Candadai, Chandler, AZ (US); Jose Fernando Waimin Almendares, Gilbert, AZ (US); Max Mohammadi Ghaleni, Phoenix, AZ (US); Ryan Joseph Carrazzone, Chandler, AZ (US); Ching-Wei Lee, Chandler, AZ (US); Chase Everett Ferrone, Gilbert, AZ (US); Seyyed Yahya Mousavi, Chandler, AZ (US)

(21) Appl. No.: 19/721,842

(22) Filed: Jun. 26, 2026

(51) Int. Cl. H10W 70/60; H10W 70/05; H10W 72/20; H10W 76/153; H10W 90/00; H10W 90/10

(52) U.S. Cl. CPC H10W 70/618; H10W 70/095; H10W 72/227; H10W 90/10; H10W 90/724; H10W 76/153

(57) ABSTRACT

Methods and apparatus to connect interconnect bridges to package substrates are disclosed. An example includes an IC package having a package substrate including a cavity. An interconnect bridge is positioned in the cavity of the package substrate. The interconnect bridge includes one or more pillars. The pillars have a straight-wall profile. A layer of material encapsulates the pillars. The pillars provide at least a portion of a surface metal routing layer. A die is coupled to the pillars of the interconnect bridge.

### BACKGROUND

In many integrated circuit packages, one or more semiconductor dies can be mechanically and electrically coupled to an underlying package substrate. In some instances, the underlying package substrate can include a semiconductor-based interconnect bridge embedded therein.

### BRIEF DESCRIPTION OF THE DRAWINGS

FIG. 1 illustrates an example integrated circuit (IC) package on a printed circuit board (PCB).

FIG. 2 is a cross-sectional view of an example IC package in accordance with teachings of this disclosure.

FIG. 3 is a flowchart representative of an example method to manufacture an example IC package disclosed herein.

FIGS. 4A-4F illustrate different stages in an example process of manufacturing the example IC package of FIG. 2.

FIG. 5 is a cross-sectional view of an example IC package in accordance with teachings of this disclosure.

FIG. 6 is a flowchart representative of an example method to manufacture an example IC package disclosed herein.

FIGS. 7A-7J illustrate different stages in an example process of manufacturing the example IC package of FIG. 5.

FIG. 8 is a cross-sectional view of an example IC package in accordance with teachings of this disclosure.

FIG. 9 is a flowchart representative of an example method to manufacture an example IC package disclosed herein.

FIGS. 10A-10I illustrate different stages in an example process of manufacturing the example IC package of FIG. 8.

FIG. 11 is a flowchart representative of an example method to manufacture an example IC package disclosed herein.

FIGS. 12A-12I illustrate different stages in an example process of manufacturing the example IC package of FIG. 8.

FIG. 13 is a cross-sectional view of an example IC package in accordance with teachings of this disclosure.

FIG. 14 is a flowchart representative of an example method to manufacture an example IC package disclosed herein.

FIGS. 15A-15F illustrate different stages in an example process of manufacturing the example IC package of FIG. 13.

FIG. 16 is a top view of a wafer including dies that may be included in an IC package constructed in accordance with teachings disclosed herein.

FIG. 17 is a cross-sectional side view of an IC device that may be included in an IC package constructed in accordance with teachings disclosed herein.

FIG. 18 is a cross-sectional side view of an IC device assembly that may include an IC package constructed in accordance with teachings disclosed herein.

FIG. 19 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all these lines and/or boundaries may be idealized. In reality, the boundaries and/or lines may be unobservable, blended, and/or irregular.

### DETAILED DESCRIPTION

An Embedded Multi-die Interconnect Bridge (EMIB) enables high-density, high-bandwidth interconnects between heterogeneous dies on a single package with low latency and high power efficiency. An EMIB is a bridge, typically a silicon bridge, embedded directly into a package substrate, such as an organic substrate, at locations requiring dense interconnect routing. EMIB technology contrasts with conventional approaches that utilize full silicon interposers spanning an entire module footprint. EMIB structures often feature a compact form factor and incorporate fine-pitch micro-bump connections enabling increased interconnect density. More recent developments incorporate thru-silicon-vias (TSV) into conventional EMIB (EMIB-T), enabling power to be routed directly from the bottom of the substrate package cavity containing an EMIB-T structure.

However, scaling EMIB-T technology presents challenges, particularly concerning alignment and overlay control between via and routing layers (e.g., especially when laser-based processes are employed) with reduced bump pitch. Improved overlay alignment is also beneficial for reduced bump pitch scaling. Additionally, scaling EMIB-T faces challenges related to solder resist opening (SRO) critical dimensions (e.g., a diameter or width of TSVs), which shrink with reduced bump pitch and increase reliability risks (e.g., increased risk of via cracking). As EMIB technology scales to finer bump pitch and higher interconnect density, alignment and overlay requirements between via and routing layers above the EMIB die become increasingly challenging when using conventional fabrication methods. Shrinking pitch directly tightens the via-to-pad overlay budget, while multiple independent contributors—including die placement variation, lithography overlay error, critical dimension (CD) variation, and thermal mismatch between die and substrate—accumulate to consume this budget and possibly cause defectivity. Thus, existing approaches rely heavily on continued tool overlay improvements, tighter process control, etc. However, these solutions face diminishing returns and increasing cost as scaling progresses, and do not fundamentally remove the sensitivity to misalignment between independently patterned layers. As EMIB continues to scale, a different fabrication approach is needed to reduce or eliminate relative overlay error between via and routing structures, rather than attempting to compensate for it through incremental tool improvements.

Example apparatus, methods and articles of manufacture disclosed herein facilitate scaling, improve interconnect density, enable silicon top die area savings, and/or enhance overall product performance. Specifically, the disclosed methods and apparatus improve alignment and/or overlay between via and routing layers and bumps of an EMIB and/or enable pitch scaling below 25 micrometers (μm) (e.g., between 5 micrometers and 20 micrometers, 10 micrometers, 15 micrometers, 16 micrometers, etc.). In some examples, the example methods and apparatus disclosed herein improve bump pitch scaling and alignment through the incorporation of prefabricated dies (e.g., EMIB dies) having pre-formed, plated copper pillars. For example, an example interconnect bridge disclosed herein includes at least one pillar extending from the interconnect bridge, where the pillar has a uniform width (e.g., diameter) along a full length of the pillar from a first end at the interconnect bridge to a second end distal from the interconnect bridge.

Providing preformed pillars with the interconnect bridge bypasses the need to buildup multiple metal layers as would be done in corresponding layers for the core bumps. These pillars are subsequently revealed and/or directly metallized to provide pads or bumps, reducing the number of lithography and laser alignment steps, and thereby enhancing manufacturing yield (e.g., and facilitating finer pitch scaling). In one approach, a dry etch process creates protruding pillars, functioning as surface pads. In another approach, a masked dry etch can be employed to form inverse traces and pads, which are subsequently filled using a damascene process, allowing for arbitrary pad sizes and increased process flexibility.

Some examples disclosed herein employ a “zero misalignment via” (ZMV) approach, employing lithography alignment to reduce (e.g., minimize) overlay errors. Another embodiment incorporates a dual lithography process leveraging all lithography patterning techniques to compensate for potential bridge die shift and ensure accurate top die placement. As used herein, an all-lithography patterning technique refers to a fabrication method that replaces laser-based processes (e.g., excimer laser drilling) with photolithography (lithography) for creating features such as vias, traces, and surface metallization in EMIB structures. For example, a front-side or top-side patterning for resulting features of an IC package that are on a package substrate's topography or interconnect pattern can be provided using solely lithography patterning process (e.g., an all lithography patterning process). This approach leverages photolithographic operations to achieve higher alignment precision, reduce process complexity, and improve overlay control compared to traditional laser-based methods. Key advantages include better alignment tolerance and reduced sensitivity to thermal distortion, reduced number of manufacturing processes, lowering manufacturing costs and improving yield, compatibility with existing lithographic tools and processes, enabling scalable production. This technique is particularly useful in EMIB scaling, where precise control over fine-pitch interconnects (e.g., below 25 μm pitch) is critical for high-performance packaging. The examples disclosed herein improve reliability, reduce manufacturing costs, and enhance competitiveness compared to alternative interconnect solutions.

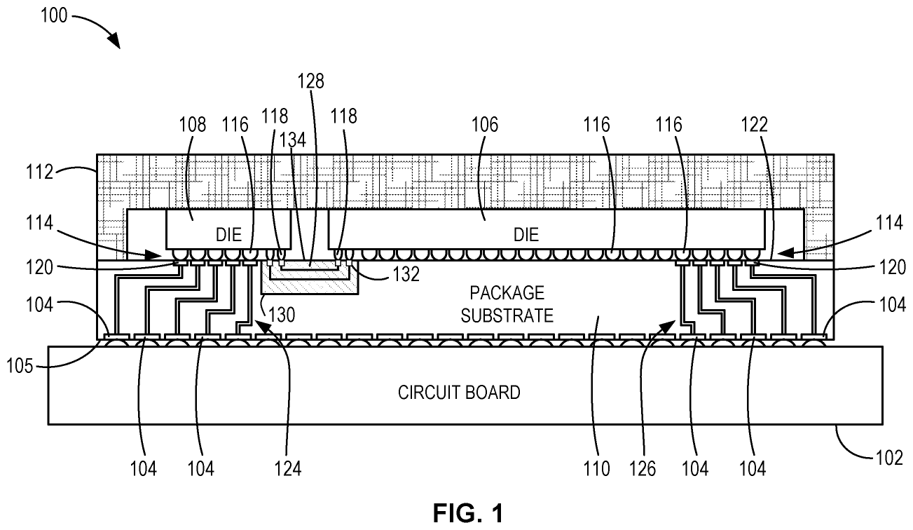

FIG. 1 illustrates an example IC package 100 (e.g., a semiconductor package) constructed in accordance with teachings disclosed herein. In the illustrated example, the IC package 100 is conductively (e.g., electrically) coupled to an example circuit board 102 via an array of example contact or landing pads 104 on an example mounting surface 105 (e.g., a bottom (external) surface) of the IC package 100. In some examples, the IC package 100 may include balls, pins, and/or pads, in addition to or instead of the landing pads 104, to enable the conductive coupling of the IC package 100 to the circuit board 102. In this example, the IC package 100 includes two example semiconductor (e.g., silicon) dies 106, 108 (sometimes also referred to as chips or chiplets) that are mounted to an example package substrate 110 and enclosed by an example package lid or mold compound 112. The package substrate 110 is the illustrated example is shown generically, but the package substrate 110 includes a core, a first plurality of alternating dielectric and conductive layers provided on a first side of the core, and a second plurality of alternating dielectric and conductive layers provided on a second side of the core opposite the first side. The core includes one or more thru-vias to electrically couple one or more of the first conductive layers and one or more of the second conductive layers. While the example IC package 100 of FIG. 1A includes two dies 106, 108, in other examples, the IC package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

In the illustrated example, each of the dies 106, 108 is conductively and mechanically coupled to the package substrate 110 via corresponding arrays of example interconnects 114. In FIG. 1, the interconnects 114 are shown as bumps. However, the interconnects 114 may be any other type of electrical connection in addition to or instead of the bumps shown (e.g., balls, pins, pads, wire bonding, etc.). The electrical connections between the dies 106, 108 and the package substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps, namely, example core bumps 116 and example bridge bumps 118. As used herein, core bumps are bumps on dies through which electrical signals pass between the dies 106, 108 and other components either within an IC package containing the dies (e.g., a different die) or external to the IC package 100. Thus, as shown in the illustrated example, when the dies 106, 108 are mounted to the package substrate 110, the core bumps 116 are physically connected and conductively coupled to contact pads 120 on an example inner surface 122 of the package substrate 110. The contact pads 120 on the inner surface 122 of the package substrate 110 are conductively coupled to the landing pads 104 on the mounting surface 105 of the package substrate 110 (e.g., a surface opposite the inner surface 122) via example internal interconnects 124, 126 within the package substrate 110. As a result, there is a complete signal path between the core bumps 116 of the dies 106, 108 and the landing pads 104 mounted to the circuit board 102 that pass through the contact pads 120 and the internal interconnects 124, 126 provided therebetween.

As used herein, bridge bumps are bumps on the dies through which electrical signals pass between different ones of the dies 106, 108 within the IC package 100. More particularly, the bridge bumps 118 differ from the core bumps 116 in that bridge bumps 118 electrically connect two or more different dies (e.g., the dies 106, 108) via an interconnect bridge 128 embedded in an underlying substrate (e.g., the package substrate 110). The interconnect bridge 128 is also known as an Embedded Multi-Die Interconnect Bridge (EMIB). An Embedded Multi-Die Interconnect Bridge that includes through-substrate-vias (TSVs) is known as an EMIB-T. In the illustrated example of FIG. 1, the example interconnect bridge 128 is electrically and mechanically coupled to the package substrate 110. In this example, the interconnect bridge 128 is positioned within an example cavity 130 in the inner surface 122 of the package substrate 110.

In some examples, the interconnect bridge 128 constitutes and/or can be implemented as an example semiconductor die (e.g., similar to the die 106, the die 108, etc.). For example, the interconnect bridge 128 is fabricated from a semiconductor wafer in a manner similar to the dies 106, 108. Thus, the interconnect bridge 128 is also sometimes referred to herein as a semiconductor die or a semiconductor-based interconnect bridge. However, in some examples, the semiconductor die that serves as the interconnect bridge 128 does not include any active semiconductor devices (e.g., does not include transistors). In other examples, the semiconductor die that serves as the interconnect bridge 128 includes active semiconductor devices. The interconnect bridge 128 includes contact or surface pads 132 (e.g., bump pads, contact pads, flip-chip pads, die-side pads, etc.) on a surface 134 (e.g., an upper surface, a surface metal routing layer) of the interconnect bridge 128 that mechanically and electrically couple to the bridge bumps 118. In examples where the interconnect bridge 128 is an EMIB-T die (e.g., with TSVs), the interconnect bridge 128 includes additional contact or surface pads and/or bumps on the opposite surface (e.g., the bottom surface) of the interconnect bridge 128 that electrically connect with internal interconnects in the package substrate 110.

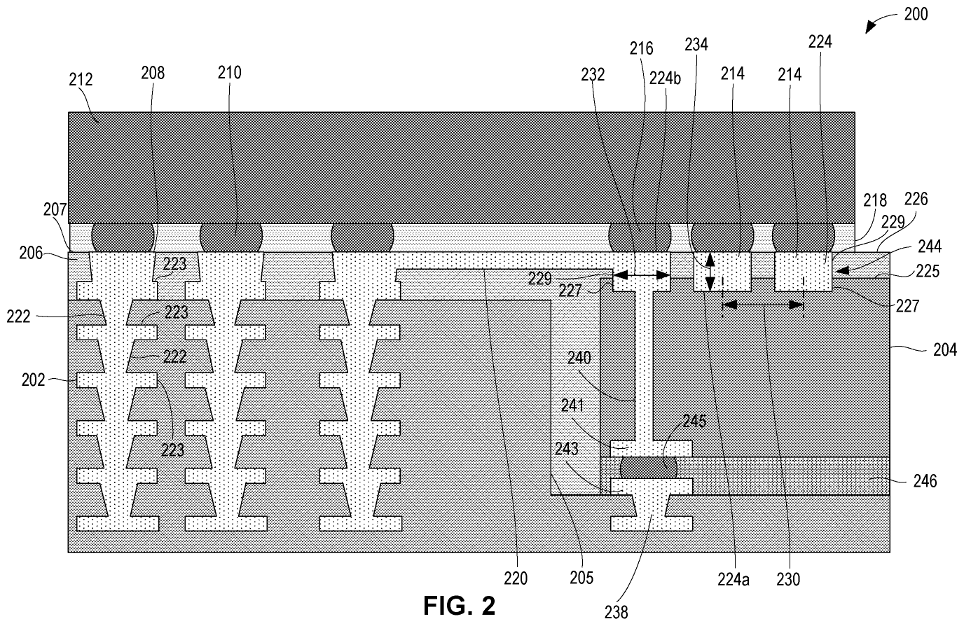

FIG. 2 is a cross-sectional view of an example IC package 200 in accordance with teachings of this disclosure. The IC package 200 of the illustrated example includes a package substrate 202 and an interconnect bridge 204. In some examples, the package substrate 202 can implement the example package substrate 110 of FIG. 1. Referring to FIG. 2, the interconnect bridge 204 is provided (embedded) in a cavity 205 of the package substrate 202. The package substrate 202 of the illustrated example includes an encapsulation layer 206 having a surface metal routing layer 207 that includes first surface pads 208 to couple with core bumps 210 of a die 212 (e.g., the die 108 of FIG. 1) and second surface pads 214 to couple with bridge bumps 216 of the die 212. The encapsulation layer 206 can include a solder resist material, a polyimide material and/or any other suitable material(s). An underfill material 218 fills a gap between the die 212 and the underlying package substrate 202. The underfill layer 218 surrounds and electrically isolates the core bumps 210 that electrically connect the die 212 and the package substrate 202 and the bridge bumps 216 that electrically connect the die 212 and the interconnect bridge 204. A trace 220 couples the package substrate 202 and the interconnect bridge 204. For example, the trace 220 couples a first one of the first surface pads 208 of the package substrate 202 and a first one of the second surface pads 214 of the interconnect bridge 204.

The package substrate 202 of the illustrated example includes a plurality of conductive vias 222 and contact or landing pads 223 provided through alternating dielectric layers and conductive layers. The conductive vias 222 and landing pads 223 are formed in the package substrate 202 using conventional methods (e.g., lithography, laser, patterning, seeding, etc.). The first surface pads 208 couple with respective ones of the conductive vias 222.

The interconnect bridge 204 includes one or more pillars 224 to couple to the interconnect bridge 204 to the die 212. The pillars 224 protrude relative to or extend away (e.g., cantilevered) from a first surface 225 (e.g., an upper surface) of the interconnect bridge 204 oriented toward the die 212. In the illustrated example, the pillars 224 extend from the interconnect bridge 204. The pillars 224 have respective ends that are flush with or exposed relative to the first surface 226 of the package substrate 202 (e.g., the encapsulation layer 206). In some examples, the pillars 224 can protrude or extend away from the first surface 226. Thus, each pillar 224 provides a respective one of the second surface pads 214 that couples to a respective one of the bridge bumps 216 of the die 212. The pillars 224 are plated with a conductive material (e.g., copper). In this example, the pillars 224 directly couple to bridge bumps 216 of the die 212.

The pillars 224 have a bump pitch 230. In some examples, the bump pitch 230 is less than 25 micrometers (μm) (e.g., 10 micrometers, 15 micrometers, 16 micrometers, etc.). In some examples, the bump pitch 230 is equal to or exceeds 25 micrometers (μm). Additionally, the pillars 224 of the interconnect bridge 204 have a width 232 (e.g., a critical dimension (CD) or diameter). In the illustrated example, the width 232 is substantially uniform or substantially straight along a thickness or length 234 (e.g., an entire length or height in a build-up or stack-up direction) of the pillars 224 between a first end 224a (e.g., a proximal end) of the pillars 224 (e.g., coupled to interconnect bridge 202) and a second end 224b (e.g., a distal end) of the pillars 224 (e.g., coupled to the bridge bumps 216) opposite the first end 224a. Thus, the pillars 224 have a uniform width (e.g., diameter) along a full length of the pillars 224 from a first end at the interconnect bridge 204 to a second end distal from the interconnect bridge 204. Io other words, contact pads 227 of the interconnect bridge 204 from which the pillars 224 protrude have the same width as a portion 229 of the pillars 224 that extend or protrude from the contact pads 227 and/or the interconnect bridge 204. In some examples, the portions 229 of the pillars 224 and the contact pads 227 are a uniform or single structure (e.g., made from a single operation). In some examples, the portions 229 of the pillars 224 and the contact pads 227 of the interconnect bridge 204 can be fabricated separately (e.g., in a two-part operation). In some examples, the pillars 224 can have a width (e.g., a diameter) that is different (e.g., greater or smaller) than a diameter of respective landing pads 225 of the interconnect bridge 204. Thus, a portion 229 of the pillars 224 that protrude away from the first surface 225 (e.g., an upper surface) of the interconnect bridge 204 can have a diameter or width that is smaller than a diameter or width of an underlying contact pad 227 of the interconnect bridge 204 from which the pillar is electrically coupled to and protruding from (e.g., a portion of the pillars 224 that is recessed within the interconnect bridge 204 underneath the first surface 225). The different diameters or widths between the portions 229 of the pillars 224 extending away from the interconnect bridge 204 and the underlying contact pads 227 can accommodate for alignment error because the pillars 224 and the underlying contact pads 227 can be fabricated (e.g., patterned) in separate operations or processes. The width 232 provides a critical dimension that is typically larger and uniform compared to critical dimensions of vias or pillars formed with conventional techniques (e.g., laser). The pillars 224 enable a larger critical dimension (CD) or diameter while reducing bump pitch. The length 234 of the pillars 224 can be, for example, between approximately 6 micrometers and 12 micrometers, and/or any other suitable length. As used herein, substantially uniform or substantially straight means a lateral or vertical profile that is perfectly vertical or lateral or within 10 percent of perfectly vertical or lateral. In other words, substantially straight means a non-conical shape (e.g., a non-tapered shape). For example, the pillars 224 have a straight-wall (e.g., a non-conical) profile (e.g., in a vertical direction in the orientation of FIG. 2). For example, the pillars 224 have uniform diameters along entire lengths (e.g., vertical heights) of the pillars 224. In some examples, the pillars 224 have a cylindrical shape. In some examples, the pillars 224 can have a rectangular shape, a square shape, and/or any other desired shape.

Additionally, the interconnect bridge 204 includes a TSV 240 to couple one or more of the pillars 224 with one or more electrically conductive layers 238 of the package substrate 202. Thus, the example interconnect bridge 204 in FIG. 2 is an EMIB-T die. In the illustrated example, a contact pad 241 (e.g., an electrically conductive contact or bump) is provided along a bottom side of the interconnect bridge 128 (e.g., opposite the pillars 224). In some examples, the interconnect bridge 204 can include individual vias and/or traces associated with distinct internal interconnects within the package substrate 202. In some examples, if the interconnect bridge does not include the TSV 240 (i.e., the interconnect bridge 204 is an EMIB), the conductive contact pad 241 can be replaced with an adhesive layer. The TSV 240 is formed with the interconnect bridge 204, like the pillars 224, prior to attachment of the interconnect bridge 204 with the package substrate 202. The TSV 240 and the pillars 224 provide an electrical coupling between the interconnect bridge 204 and the package substrate 202, which enables power and/or signals to be routed directly from a trace or conductive layer (e.g., a signal trace, a power trace, etc.) in communication with the cavity 205 (e.g., a bottom surface of the cavity in the orientation of FIG. 2). Thus, the pillars 224 provide electrical connections between the interconnect bridge 204 and the package substrate 202, providing a direct path for power delivery and/or signal transmission. For example, to couple the interconnect bridge 204 and the package substrate 202, the contact pad 241 of the interconnect bridge 204 is coupled (e.g., soldered or bonded) with a landing pad 243 within the cavity 205. In this example, a solder material or solder pad 245 (e.g., tin (Sn)) is provided between the landing pad 243 and the contact pad 241 to improve bonding. For example, the interconnect bridge 204 is coupled to the package substrate 202 via thermal compression bonding manufacturing. A non-conductive film 246 can be positioned between the interconnect bridge 204 and the package substrate 202 that encases the solder pad 245.

Additionally, the pillars 224 are an integral part of the interconnect bridge 204 (i.e., the EMIB-T die). In other words, the pillars 224 are provided (e.g., fabricated) with the interconnect bridge 204 prior to attachment with the package substrate 202 and/or prior to formation of the encapsulation layer 206 and/or the surface metal routing layer 207. Thus, when the IC package 200 employing the package substrate 202 and the interconnect bridge 204 is assembled, the pillars 224 provide single layer conductive vias 244 that provide the second surface pads 214 that couple the interconnect bridge 204 and the bridge bumps 216. For example, the pillars 224 eliminate the need for providing alternating layers of landing pads and vias (e.g., multiple build-up layers) between the interconnect bridge 204 and the die 212 (e.g., that would normally be needed to provide surface bumps or pads). Therefore, additional manufacturing processes including lithography, etching, seed layers, etc., can be omitted that would otherwise be needed to build the vias and contact pads that would otherwise be needed to couple the interconnect bridge 204 and bridge bumps 216. In other words, additional layers between the interconnect bridge 204 and the bridge bumps 216 of the encapsulation layer 206 to form alternating vias and surface pads are omitted, thereby reducing manufacturing steps or processes. Instead, the pillars 224 extend through the encapsulation layer 206. Specifically, the pillars 224 extend continuously from the interconnect bridge 204 to an outer surface (e.g., the first surface 226) of the package substrate 202 (or at least continuously up to a solder resist layer or the encapsulation layer 206) on the first surface 226 (e.g., an outer surface) of the package substrate 202.

The interconnect bridge 204 of the illustrated example is prefabricated or pre-formed with the pillars 224 (e.g., copper plated pillars). Pre-forming the interconnect bridge 204 with the pillars 224 prior to coupling with the package substrate 202 enables achievement of pitch scaling that is less than 25 micrometers (μm) (e.g., 15 micrometers). Additionally or alternatively, providing the pillars 224 with the formation of the interconnect bridge 204 eliminates or reduces overlay alignment offset issues that may otherwise have occurred during a build-up process (e.g., when bump pitch is less than 25 micrometers). The IC package 200 of the illustrated example improves reliability, reduces manufacturing costs, and enhances competitiveness compared to alternative interconnect solutions.

Generally, the surface metal routing layer 207 (e.g., the example contact pads 208 and the landing pads 223) of the IC package 200 of FIG. 2 is fabricated using a dual damascene process to improve overlay alignment tolerance compared to conventional methods, and a zero misalignment process by providing routing traces (e.g., the trace 220) and vias patterning (e.g., surface pads 208) in a single operation. Additionally, the process of fabricating the IC package 200 enables fabrication of vias or pillars with a larger critical diameter, thereby improving structural integrity while reducing bump pitch scaling (e.g., bump pitch scaling to 15 micrometers).

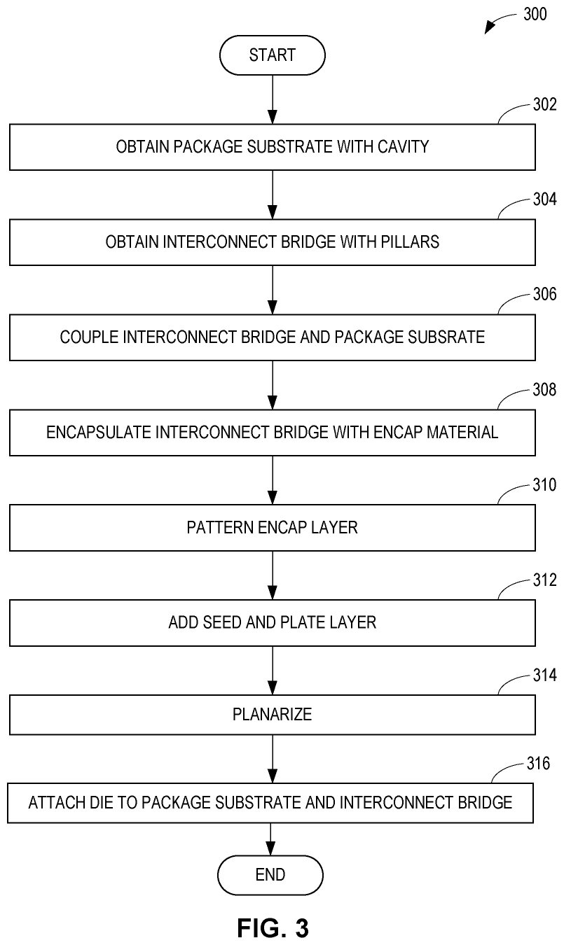

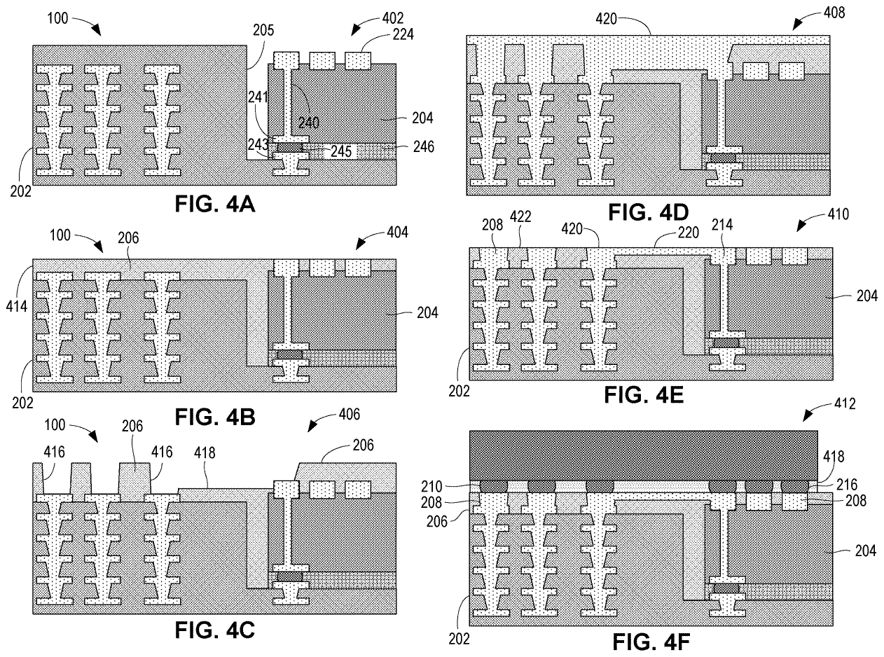

FIG. 3 is a flowchart of an example method 300 of fabricating an example IC package 200 (e.g., the package substrate 202 of FIG. 2). To facilitate discussion of the example method 300, the example method 300 is described in connection with the example IC package 200 of FIG. 2. For example, FIGS. 4A-4F are cross-sectional schematic illustrations of the example IC package 200 of FIG. 2 at various manufacturing stages 402, 404, 406, 408, 410, 412, corresponding to the example method 300 of FIG. 3. While an example manner of fabricating the example package substrate 202 has been illustrated in FIGS. 3 and 4A-4F, one or more of the operations and/or processes illustrated in FIGS. 3 and 4A-4F may be combined, divided, re-arranged, omitted, eliminated and/or implemented in any other way. Further still, the example methods of FIGS. 3 and 4A-4F may include processes and/or operations in addition to, or instead of, those illustrated in FIGS. 3 and 4A-4F and/or may include more than one of any or all of the illustrated processes and/or operations. In some examples, some or all of the operations outlined in the example method of FIG. 3 are performed automatically by fabrication equipment that is programmed to perform the operations.

Turning to FIG. 3, the example process begins at block 302 at which an example package substrate with an example cavity is provided. As shown in FIG. 4A, the package substrate 202 is formed with the cavity 205. The cavity 205 of the package substrate 202 can be formed by, for example, mechanical drilling, laser drilling, dry etching, and/or any other suitable semiconductor manufacturing process(es).

At block 304, an interconnect bridge with pillars is obtained. Referring to FIG. 4A, the interconnect bridge 204 is prefabricated with the pillars 224 and the TSV 240. The pillars 224 on the interconnect bridge 204 are prefabricated by an independent wafer fabrication stage and remain intact throughout subsequent processing operations. Thus, the interconnect bridge 204 is a prefabricated structure that is separate from the package substrate 202. The interconnect bridge 204 includes the pillars 224 and the TSV 240. By incorporating pre-fabricated pillars 224 into the interconnect bridge 204, the need for post-processing metallization is eliminated, simplifying the manufacturing process and reducing costs.

At block 306, the package substrate and the interconnect bridge are coupled. As shown in FIG. 4A, the interconnect bridge 204 is positioned in the cavity 205 of the package substrate 202 after formation of the cavity 205. The interconnect bridge 204 can couple to the package substrate 202 by a bonding process and/or any other process. For example, the contact pad 241 electrically couple with the landing pad 243 of the package substrate 202 (e.g., a power source) via the solder pad 245, thereby electrically coupling the package substrate 202 with one or more of the pillars 224 (e.g., via the TSV 240). The non-conductive film 246 is provided between the package substrate 202 and the interconnect bridge 204.

At block 308, the interconnect bridge is encapsulated with an encapsulating material. As shown in FIG. 4B, the interconnect bridge 204 is encapsulated with an encapsulating material 414. The encapsulating material 414 provides the encapsulation layer 206. The encapsulating material 414 can include a solder resist material, a polyimide material, an build-up film, a dielectric build-up film,, an epoxy-based build-up film or layer, and/or any other suitable dielectric material(s). The method of attachment of the die 212 with the package substrate 202 (e.g., as shown in FIG. 4F) can determine which type of encapsulating material 414 is employed. For example, for hybrid bonding, the encapsulating material 414 can be polyimide. For soldering, the encapsulating material can be solder resist.

At block 310, the encapsulation layer is patterned with features to provide a surface metal pattern/routing layer. As used herein, features can include, but are not limited, interconnect features, metal traces, pads, vias, redistribution layers (RDL) and/or any other feature(s) for providing a surface metal routing layer for implementing a semiconductor die. Referring to FIG. 4C, one or more via openings 416 and routing traces 418 are patterned in the encapsulation layer 206 to provide the surface metal routing layer 207. The via openings 416 and routing traces 418 can be patterned using lithography, laser, dry etching in conjunction with excimer laser for enhanced precision and control, and/or any other patterning technique(s). To this end, because the routing traces 418 and the via openings 416 are patterned in single process, overlay alignment tolerance is significantly improved compared to conventional approaches that require multiple layers or operations to form the same routing traces and/or vias.

At block 312, a seed and plate layer is applied. As shown in FIG. 4D, a seed layer (e.g., a thin conductive film) is provided, followed by a plate layer 420 to fill the via openings 416 and the routing traces 418 with a conductive material. A seed layer can include copper, titanium, nickel, gold, and/or any other conductive material(s). The seed layer can be provided by physical vapor deposition (PVD/sputtering), chemical vapor deposition (CVD), atomic layer deposition (ALD) and/or any other semiconductor fabrication technique(s). The plate layer is grown on top of the seed layer using electroplating. The plate layer can include copper, nickel, gold, tin, solder alloys, and/or any other suitable material(s). Electroplating processes includes submerging the assembly in a chemical bath and applying a current that causes metal ions to deposit onto the seed layer.

At block 314, the assembly is planarized. Referring to FIG. 4E, planarization is employed to remove excess material and smooth surface irregularities on an upper surface 422 of the encapsulation layer 206. Planarization promotes optimal alignment and reduces defects in subsequent processing operations. Planarization can be provided by mechanical grinding, chemical mechanical planarization (CMP), etching, polishing and/or any other suitable semiconductor manufacturing process(es). In some examples, to prevent oxidation before coupling of the die, a layer of organic solderability preserve can be applied after planarization.

Referring to FIG. 4E, when planarization is complete, the seed and plate layer 420 provides a conductive layer including the trace 220 and the second surface pads 214 of the interconnect bridge 204 and the first surface pads 208 of the package substrate 202. Because the trace 220 is formed with the surface pads 208 and 214, alignment or overlay issues with the trace 220 are eliminated or avoided. Further, as shown in FIG. 4E, due to the extent that the surface pads 214 protrude above the interconnect bridge 204, the pillars 224 extend up to the upper surface 422 of the encapsulation layer 206 (after the planarization) without the need to add any intermediate metal features (e.g., vias, pads, etc.) to define conductive paths between the interconnect bridge 204 and the upper surface 422.

At block 316, a die is attached to the package substrate. Referring to FIG. 4F, the bridge bumps 216 of the die 212 couple to the second surface pads 214 (i.e., the pillars 224) of the interconnect bridge 204 and the core bumps 210 of the die 212 couple to the first surface pads 208 of the package substrate 202 via. In this example, the encapsulation layer 206 is substantially flush after planarization of FIG. 4E. In this example, the die 212 can be attached to the package substrate 202 and the interconnect bridge 204 via hybrid bonding. If hybrid bonding is employed, the encapsulation material 414 of FIG. 4B can be a polyimide. Alternatively, in some examples, the die 212 can couple to the package substrate 202 and the interconnect bridge 204 via soldering. In this example, the encapsulation material 414 can be a solder resist material. Additionally, if a soldering technique is employed, after planarization and prior to die attachment, the encapsulation layer 206 can be etched back to expose the surface pads 208, 214 (e.g., expose the copper or conductive material, expose ends of the pillars 224, etc.). In other words, etching back the encapsulation layer 206 exposes or causes the surface pads 208, 214 to protrude away from the encapsulation layer 206. After die attachment, the underfill layer 218 (FIG. 2) can be provided to fill a gap around the core bumps 210 and the bridge bumps 216.

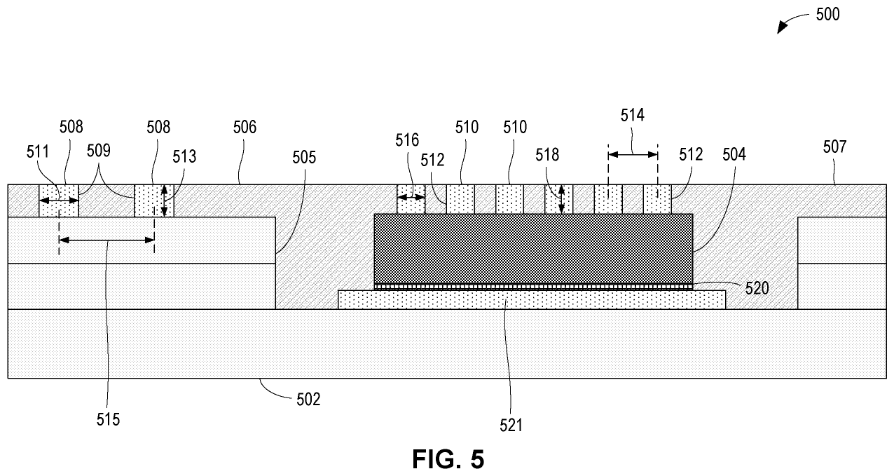

FIG. 5 is a partial, cross-sectional view of another example IC package 500 in accordance with teachings of this disclosure. The IC package 500 of the illustrated example includes a package substrate 502 and an interconnect bridge 504. In some examples, the package substrate 502 can implement the example package substrate 110 of FIG. 1. Referring to FIG. 5, the interconnect bridge 504 is provided (embedded) in a cavity 505 of the package substrate 502. The package substrate 502 of the illustrated example includes an encapsulation layer 506 having a surface metal pattern layer 507 that includes first surface pads 508 (e.g., core vias) to couple with core bumps of a die (e.g., the core bumps 116 of the die 108 of FIG. 1) and second surface pads 510 (e.g., bump vias) to couple with bridge bumps of the die (e.g., the bridge bumps 118 of the die 108 of FIG. 1). In some examples, the surface metal pattern layer 507 can include one or more vias, traces, contacts, pads, and/or any other interconnect features. The encapsulation layer 506 can includes ABF, polyimide, and/or any other similar material(s).

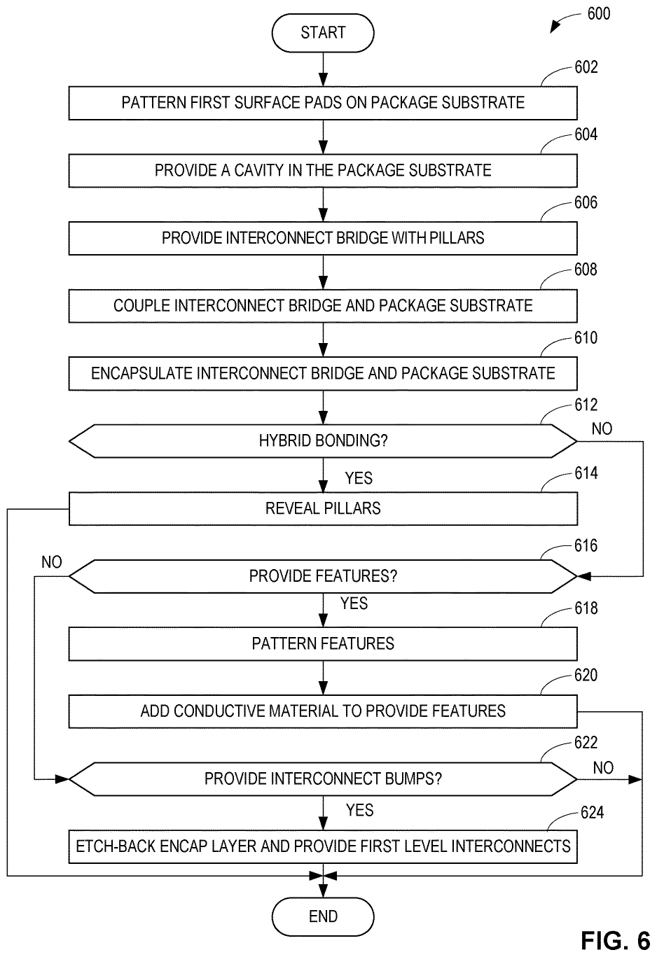

To provide the first surface pads 508, the package substrate 502 of the illustrated example includes a plurality of first pillars 509 provide during formation of the package substrate 502. The first pillars 509 of the package substrate 502 have a width 511 (e.g., a diameter). The width 511 is substantially uniform along a width or length 513 (e.g., an entire length or height in a build-up direction) of the first pillars 509. The length 513 of the first pillars 509 can be, for example, between approximately 6 micrometers and 12 micrometers. The first pillars 509 have a straight-wall profile (e.g., a non-conical or uniform diameter profile in a vertical direction in the orientation of FIG. 5). In some examples, the first pillars 509 can have a rectangular shape, a square shape, a cylindrical shape, and/or any other shape. As described below in connection the FIG. 6, the first pillars 509 are provided via lithography.

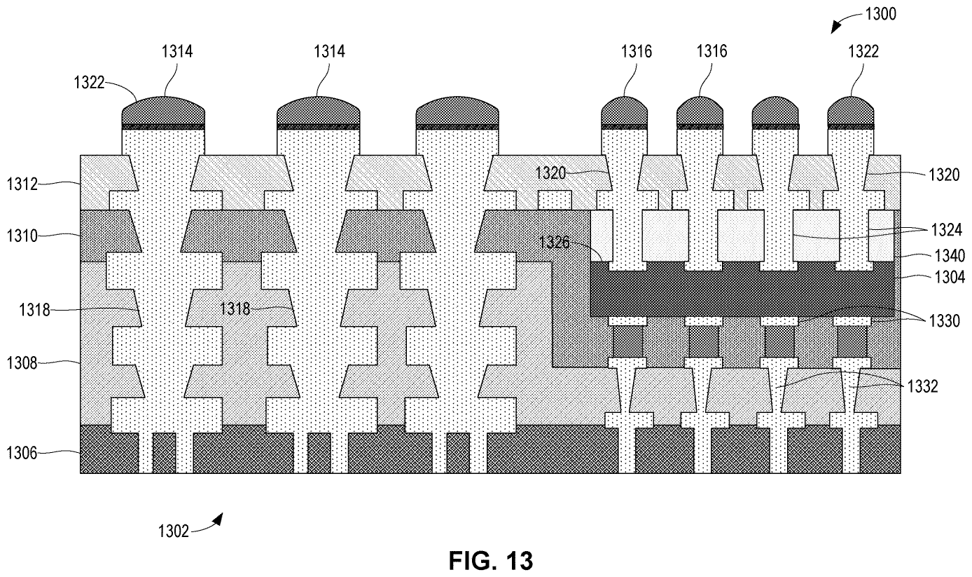

To provide the second surface pads 510, the interconnect bridge 504 includes a plurality of second pillars 512. The second pillars 512 are provided separately from (e.g., prior to) formation of the package substrate 502. The second pillars 512 are an integral part of the interconnect bridge 504 (i.e., an EMIB die, an EMIB-T die, etc.). In other words, the second pillars 512 are formed with the interconnect bridge 504 prior to attachment with the package substrate 502 and/or prior to formation of the encapsulation layer 506 (e.g., and prior to formation of the first pillars 509). The second pillars 512 have a bump pitch 514. In some examples, the bump pitch 514 is less than 25 micrometers (μm) (e.g., 15 micrometers). In some examples, the bump pitch 514 is equal to or exceeds 25 micrometers (μm). Additionally, the second pillars 512 of the interconnect bridge 504 have a width 516 (e.g., a diameter). In the illustrated example, the width 516 is substantially uniform along a width or length 518 of the second pillars 512 (e.g., a non-conical or uniform diameter profile in a vertical direction in the orientation of FIG. 5). The length 518 of the second pillars 512 can be, for example, between approximately 6 micrometers and 12 micrometers. The second pillars 512 have a cylindrical shape. In some examples, the second pillars 512 can have a rectangular shape, a square shape, and/or any other shape. The interconnect bridge 504 has an adhesive layer 520 (e.g., on a surface opposite the second pillars 512) that couples to a pad 521 (e.g., a copper pad) exposed through the cavity 505 of the package substrate 502. In this manner, the adhesive layer 520 adheres or couples the interconnect bridge 504 and the package substrate 502 Thus, the second pillars 512 provide electrical connections between the interconnect bridge 504 and the package substrate 502, providing a direct path for power delivery and/or signal transmission. In some examples, the interconnect bridge 504 can include a TSV (e.g., the TSV 240 of FIG. 2) (e.g., an EMIB-T) to communicatively couple the second pillars 512 and one or more discrete contact pads (e.g., that would be formed on the interconnect bridge 504 in place of the adhesive layer 520). In some examples, the contact pad 521 can include an array of contacts or pads that attach to corresponding array of contacts or pads on a bottom surface of the interconnect bridge 504 (see e.g., FIG. 13).

The first pillars 509 and the second pillars 512 extend through the encapsulation layer 506. Specifically, the first pillars 509 extend continuously from the package substrate 502 to an outer surface of the encapsulation layer 506. Additionally, the pillars 512 extend continuously from the interconnect bridge 504 to an outer surface (e.g., the surface metal routing layer 507). In this manner, the pillars 509, 512 bypass the need to buildup multiple metal layers as would be done in corresponding layers for the core bumps/pads or bridge bumps/pads. The pillars 509 and the pillars 512 have a uniform width along a full length of the pillars 509, 512. The pillars 512 extend continuously from a first end at the interconnect bridge 504 to a second end distal from the interconnect bridge 504.

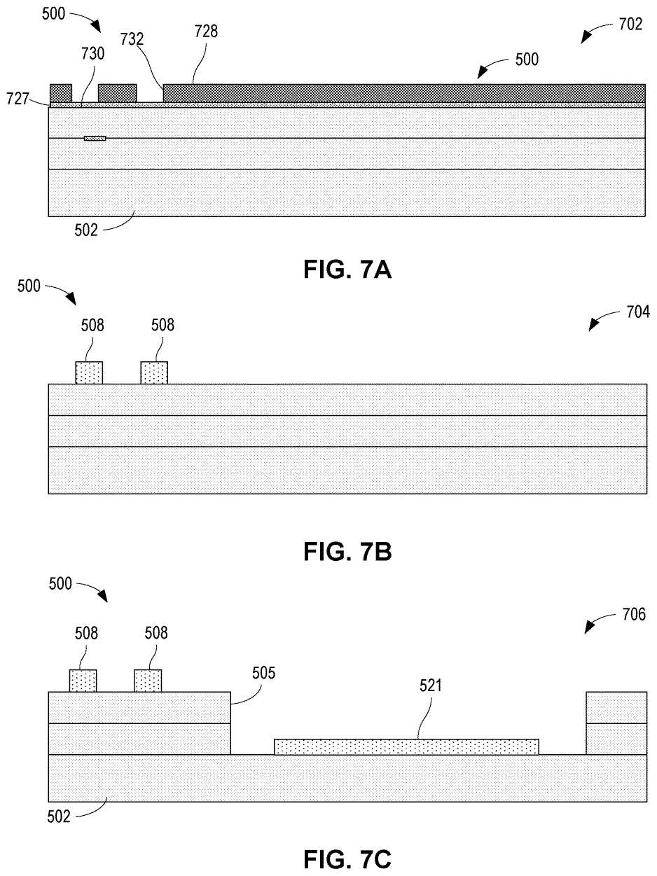

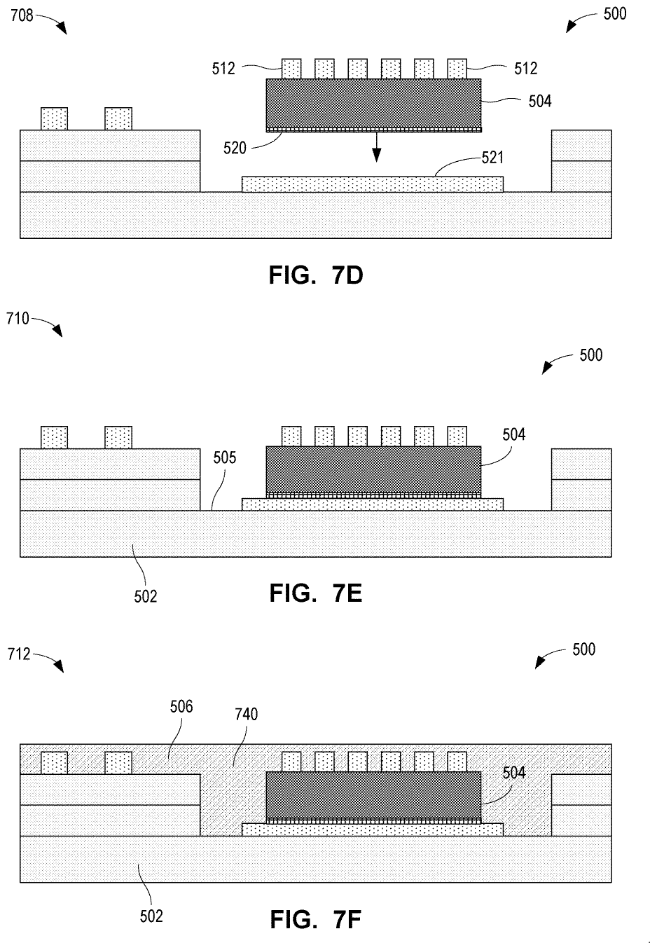

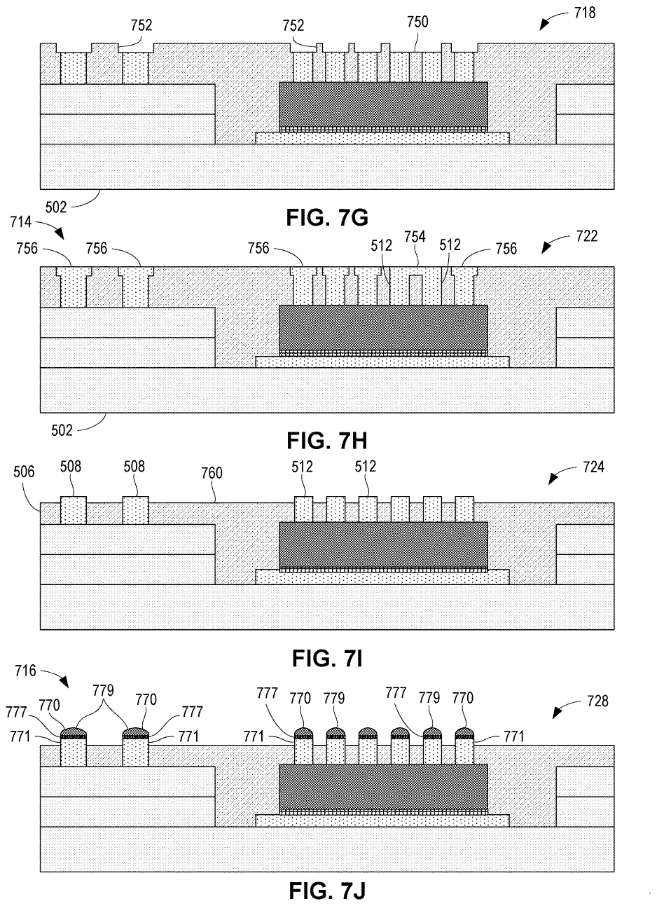

In the illustrated example, the first pillars 509 can have different shapes and/or sizes compared to the second pillars 512. For example, the thickness 516 can be the same or different (e.g., greater, equal, or less) than the width 511, the length 518 can be the same or different (e.g., greater, equal, or less) than the length 513 and/or the bump pitch 514 can be the same or different (e.g., greater, equal, or less) than a bump pitch 514 of the first pillars 509. In some examples, the IC package 500 can include surface pads 756 as shown in FIG. 7H or first level interconnects 770 (e.g., bumps) as shown in FIG. 7J.

Typically, with interconnect bridge process flows, first level interconnect bump pitch scaling (e.g., bump pitch of less than 25 micrometers) can present challenges imposed by propagation of overlay offsets of subsequent lithography and laser processes that are typically used for creating micro bumps over interconnect bridges. The example IC package 500 employs an incoming or prefabricated interconnect bridge (e.g., an EMIB die, EMIB-T die) with metal plated pillars (e.g., copper plated pillars) that are revealed and directly metallized, removing consecutive lithography/laser alignment methods. In some examples, dry etch is employed to form inverse (cavity) traces and pads, and fill them with a damascene process.

FIG. 6 is a flowchart of an example method 600 of fabricating an example IC package (e.g., the IC package 500 of FIG. 5). To facilitate discussion of the example method 600, the example method 600 is described in connection with the example IC package 500 of FIG. 5. For example, FIGS. 7A-7F are cross-sectional schematic illustrations of the example IC package 500 of FIG. 5 at various manufacturing stages 702, 704, 706, 708, 710, 712, corresponding to the example method 600 of FIG. 5. Additionally, alternative IC packages 714 and 716 are shown in FIGS. 7G-7J, which can be fabricated from the example manufacturing stages 702-712. FIGS. 7G-7J illustrate the alternative IC packages 714, 716 at various manufacturing stages 718-724.

While an example manner of fabricating the example package substrate 502 has been illustrated in FIGS. 6 and 7A-7F, the alternative IC package 714 of FIGS. 7G and 7H, or the alternative IC package 716 of FIGS. 7I-7J, one or more of the operations and/or processes illustrated in FIGS. 6 and 7A-7J may be combined, divided, re-arranged, omitted, eliminated and/or implemented in any other way. Further still, the example methods of FIGS. 6 and 7A-7J may include processes and/or operations in addition to, or instead of, those illustrated in FIGS. 6 and 7A-7J and/or may include more than one of any or all of the illustrated processes and/or operations. In some examples, some or all of the operations outlined in the example method of FIG. 6 are performed automatically by fabrication equipment that is programmed to perform the operations.

Turning to FIG. 7a, the example process begins at block 602 at which an example first surface pads are patterned on the package substrate. As shown in FIG. 7A, the package substrate 502 includes build-up layers of alternating dielectric and conductive layers. A seed layer 727 is provided on an upper surface 730 of the package substrate 202 (e.g., via sputtering) and a photoresist layer 728 is provided on the seed layer 727. Subsequently, via openings 732 are provided in the photoresist layer 728. The via openings 732 have a straight profile (e.g., a non-conical profile). The via openings 732 can be provided via photolithography to provide a straight-wall profile (e.g., a uniform diameter along an entire length of the via openings 732). The first surface pads 508 are plated up through the photoresist layer 728 (instead of being formed by a laser) and then filled with conductive material. The photoresist layer 728 is stripped and the seed layer 727 is flashed etched, yielding the surface pads 508 of the package substrate 502 of FIG. 7B. Thus, The via openings 732 of FIG. 7A and the first surface pads 508 of FIG. 7B are formed via photolithography (e.g., instead of laser). In this manner, employing lithography techniques to provide the first surface pads 508 produces alignment features used for mounting the interconnect bridge 504.

At block 604, an example cavity is provided in the package substrate. For example, referring to FIG. 7C, the cavity 505 is provided in a dielectric layer of the package substrate 502. The cavity 505 is formed at thickness or depth to receive (e.g., fully receive) the interconnect bridge 504 and/or to expose the metal pad 521 of the package substrate 502. The cavity 505 of the package substrate 502 can be formed by, for example, photolithography, mechanical drilling, laser drilling, dry etching, and/or any other suitable semiconductor manufacturing process(es).

At block 606, an example interconnect bridge with pillars is provided. Referring to FIG. 7D, referring to FIG. 7D, the interconnect bridge 504 is prefabricated with the second pillars 512 (e.g., and the adhesive layer 520). The second pillars 512 of the interconnect bridge 504 are prefabricated by an independent wafer fabrication stage and remain intact throughout subsequent processing steps. Thus, the interconnect bridge 504 is a prefabricated structure that is separate than the package substrate 502.

At block 608, the package substrate and the interconnect bridge are coupled. As shown in FIG. 7E, the interconnect bridge 504 is positioned in the cavity 505 of the package substrate 502 after formation of the cavity 505. As shown in FIG. 7E, the interconnect bridge 504 is positioned in the cavity 505 and the adhesive layer 520 is coupled to or bonded with the metal pad 521 of the package substrate 502. In some examples, when the interconnect bridge 504 is an EMIB-T, for example, the interconnect bridge 504 can be electrically coupled to the package substrate 502 (e.g., see FIG. 13).

At block 610, the interconnect bridge is encapsulated with an example encapsulating material. As shown in FIG. 7F, the interconnect bridge 504 is encapsulated or embedded with an encapsulating material 740 to provide the encapsulation layer 506. The encapsulating material 740 of the illustrated example is an epoxy-based dielectric material (e.g., ABF). However, in some examples, the encapsulating material 740 can be polyimide and/or any other suitable dielectric material(s). The encapsulation material 740 can be provided via a lamination process.

The method of attachment of a die with the package substrate 502 (e.g., as fabricated up to the point shown in FIG. 7F) can determine the next manufacturing processes.

At block 612, if a die is to couple to the package substrate via hybrid bonding (block 612; YES), the pillars are revealed (block 614). For example, referring to FIG. 7F, the encapsulation layer is grinded using a grinding process, a planarization process and/or any other suitable semiconductor manufacturing process(es). The encapsulation layer 506 can be planarized to reveal the surface pads 508, 510 as shown in FIG. 5. For example, chemical mechanical planarization (CMP), grinding, flycut, or similar process may be used to expose the surface pads 508, 510. In such example, the first pillars 509 provide the first surface pads 508 and the second pillars 512 provide the second surface pads 510. Accordingly, no additional fabrication processes are required to prepare the package substrate 502 to receive a die. Therefore, the example method 600 of FIG. 6 ends.

If hybrid bonding is not applicable (block 612; NO), the method 600 determines if one or more features (e.g., traces and/or pads) are to be provided (block 616). The features can include enlarged surface pads, one or more traces, etc., that are revealed.

If features are to be provided (block 616; YES), the features are patterned (block 618). Referring to FIG. 7G, the encapsulation layer 506 is patterned with a trench 750 and cavities 752 using, for example, a dual damascene process. In FIG. 7G, the trench 750 and the cavities 752 are provided by a masked dry etching process (e.g., photolithography patterning and dry etching (plasma etching) to provide the trench 750 and the cavities 752).

At block 620, conductive material is added to the patterned features (block 618). For example, after formation of the trench 750 and the cavities 752, the trench 750 and the cavities 752 are filled with a conductive material (e.g., copper, metal, etc.). For example, conductive material can be provided by depositing barrier and seed layers, and the trench 750 and the cavities 752 can be provided with the conductive material (e.g., copper) by electroplating.

Referring to FIG. 7H, excess conductive material is removed by chemical mechanical planarization (CMP) to provide the metal material only inside the trench 750 and cavities 752 (FIG. 7G), which provide a trace 754 and enlarged surface pads 756. The trace 754 couples two or more of the second pillars 512. Employing the damascene process and/or the dry etching process enables pads of arbitrary size to be formed, which enables a diameter of the second pillars 512 to be scaled to an arbitrarily larger diameter, which can provide greater margin and flexibility for a first level interconnect (FLI) metallization process.

If at block 616 features are not to be provided (block 616; NO), the method 600 determines whether to provide interconnect bumps (i.e., reveal the pillars 512) (block 622). If the interconnect bumps are not to be provided (block 622; NO), then the method 600 ends.

If the pillars 512 are to be revealed (block 622; YES), the encapsulation layer 506 is etched back and FLI are provided (block 624). Referring to FIG. 7I, a portion of the encapsulation layer 506 is etched-back or removed to expose portions of the first pillars 509 and the second pillars 512. In other words, portions of the first pillars 509 and the second pillars 512 extend beyond an upper surface 760 of the encapsulation layer 506. The etch-back can be provided with a dry etch fabrication technique, chemical thinning fabrication technique. In some examples, the etch-back can be between 5 and 10 micrometers.

Referring to FIG. 7J, first level interconnects 770 (e.g., surface contacts) are provided to the exposed potions 771 of the first pillars 509 and the second pillars 512, respectively. The exposed portions 771 provide protrusions that function as pads or bases for solder bumps. Providing the first level interconnects 770 allows for interconnect bumps without loss of alignment fidelity from the interconnect bridge 504 itself. The first level interconnects 770 can be formed using a dual lithography, first level interconnect (FLI) process. A dual lithography FLI process generally refers to an interconnect fabrication scheme that uses two separate lithography patterning steps to define ultra-fine-pitch metal features. Using the dual lithography process, a diffusion layer 777 (e.g., nickel) and a solder bump 779 (e.g., tin (Sn) plating) can be provided on the pillars 509, 512. For example, the diffusion layer 777 can be a thin seed/wettable layer provided on the pillars 509, 512, and the solder bump 779 can be a thicker solder-forming layer provided on the diffusion layer 777. The diffusion layer 777 improves adhesion or solderability and the solder bump 779 can be employed for bonding/interconnect formation. In this example, the solder bump 779 is at an end of a first one of the pillars 512 without any metal features extending laterally beyond the straight-wall profile of the first one of the first pillars 512 and the solder bump 779.

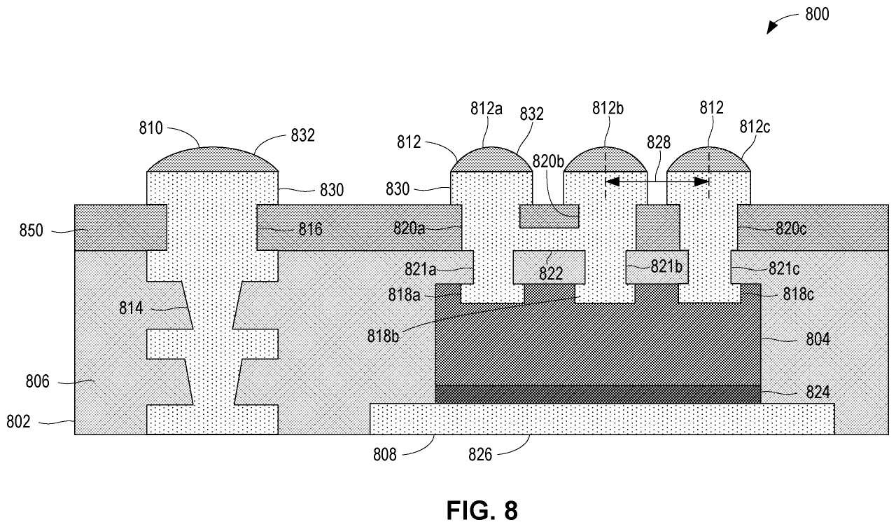

FIG. 8 is a cross-sectional view of another IC package 800 disclosed herein. The IC package 800 of the illustrated example includes a package substrate 802 and an interconnect bridge 804. The package substrate 802 and the interconnect bridge 804 can implement the example package substrate 110 and the interconnect bridge 128 of FIG. 1. The package substrate 802 includes dielectric layers 806 and conductive layers 808. The IC package 800 includes first level interconnects 810 (e.g., core bumps) to couple with core bumps of a die (e.g., the core bumps 116 of the die 108 of FIG. 1) and first level interconnects 812 to couple with bridge bumps of the die (e.g., the bridge bumps 118 of the die 108 of FIG. 1). A first level interconnect 810 couples to a conductive via 814 of the package substrate 802 via a first pillar 816 (e.g., a via). The first level interconnects 812a-c couple to contact pads 818a-c (e.g., bridge pads) on a surface of the interconnect bridge 804 via respective pillars 820a-c (e.g., vias) (e.g., first pillars) and pillars 821a-c (e.g., second pillars). The pillars 816, 820a-c and 821a-c have substantially straight-wall profiles. The pillars 820a-c, 821a-c have uniform diameters along entire lengths of the respective pillars 820a-c, 821a-c (e.g., non-conical, wall profiles). The pillars 820a and 820b (e.g., two adjacent pillars) of the illustrated example are coupled by a trace 822. Specifically, the pillars 820a-c align with (e.g., vertically align with) and electrically couple to respective ones of the pillars 821a-c. The first pillar 816, the pillars 820a-c and the trace 822 are provided in an encapsulation layer 850 (e.g., a solder resist layer) and/or a surface metal routing layer. The first level interconnects 810 and the first level interconnects 812a-c each include a surface pad 830 (e.g., provided on the encapsulation layer 850). In this example, the trace 822 aligns laterally with bottom ends or surfaces of the pillars 820a-b and is formed in the encapsulation layer 850. In this example, a bottom side of the trace 822 is flush with a bottom side of the first pillar 820a (e.g., and/or a bottom side of the second pillar 820b) that extends with a straight-wall profile all the way through the encapsulation layer 850 (e.g., a solder resist, polyimide, etc.).

The interconnect bridge 804 includes an adhesive layer 824 that couples to a conductive layer 826 of the package substrate 802. In some examples, the adhesive layer 824 and the conductive layer 826 are omitted. Instead, the interconnect bridge 804 and the package substrate 802 can include an array of connected bumps/contact pads to electrically couple the interconnect bridge 804 and the package substrate 802 (see e.g., FIG. 13). Additionally, the conductive layer 826 of the package substrate 802 can be connected to underlying vias associated with different internal interconnects within the package substrate 802 and/or the interconnect bridge 804 can be connected to vias associated with internal interconnects with the interconnect bridge 804. The first level interconnects 812a-c have a bump pitch 828 that is less than 25 micrometers. However, in some examples, the bump pitch 828 can be equal to or greater than 25 micrometers. Although only one of the conductive via 814 and the first level interconnect 810 are shown, the IC package 800 can include a plurality of conductive vias 814 and first level interconnects 810. Additionally, although only three first level interconnects 812a-c are shown, any number of first level interconnects 812 can be provided (e.g., one, two, more than three, etc.). The first level interconnects 810 and 812 are each plated with a metal material 832 (e.g., a solder bump, tin).

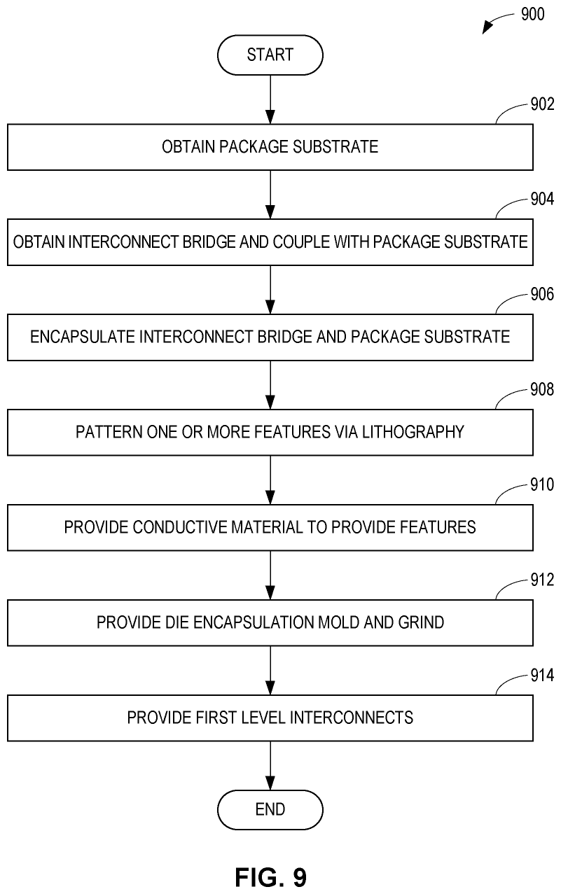

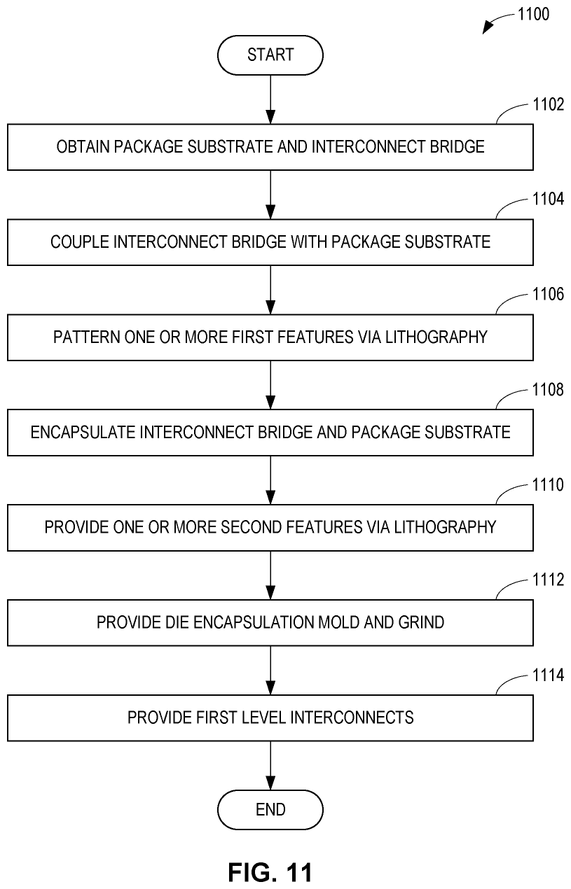

Example flow processes of FIG. 9 and FIG. 11 provide example methods of fabricating the IC package 800 of FIG. 8. The example process of FIG. 9 employs a lithography and patterning (greyscale patterning) provided by a zero misalignment approach. The example process of FIG. 11 employs a lithography-to-lithography alignment approach. Both example approaches are employed to provide bump pitch scaling below 25 micrometers (e.g., 10 micrometers, 15 micrometers, 16 micrometers, etc.).

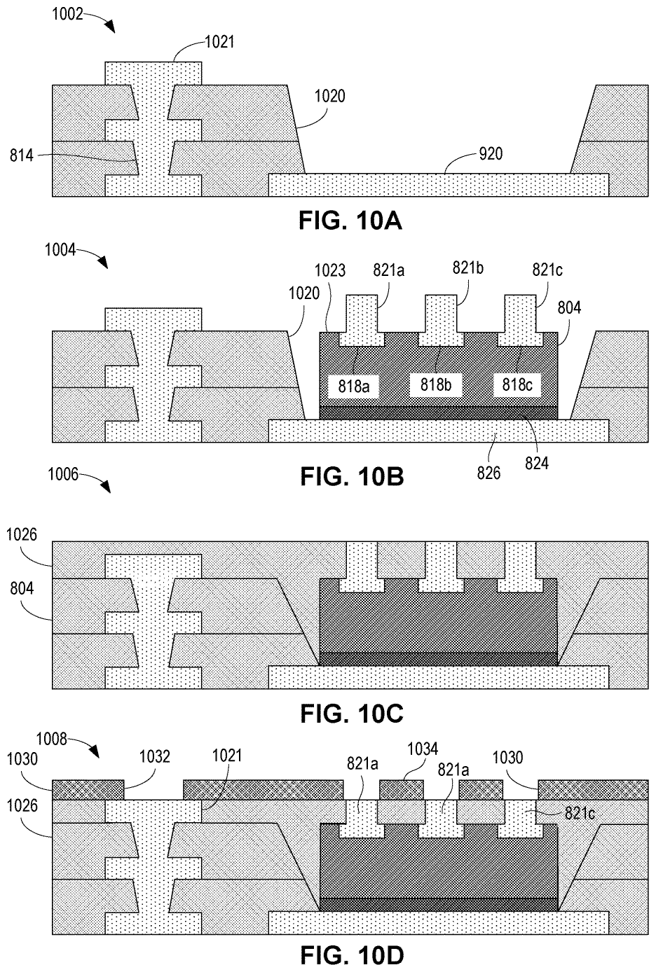

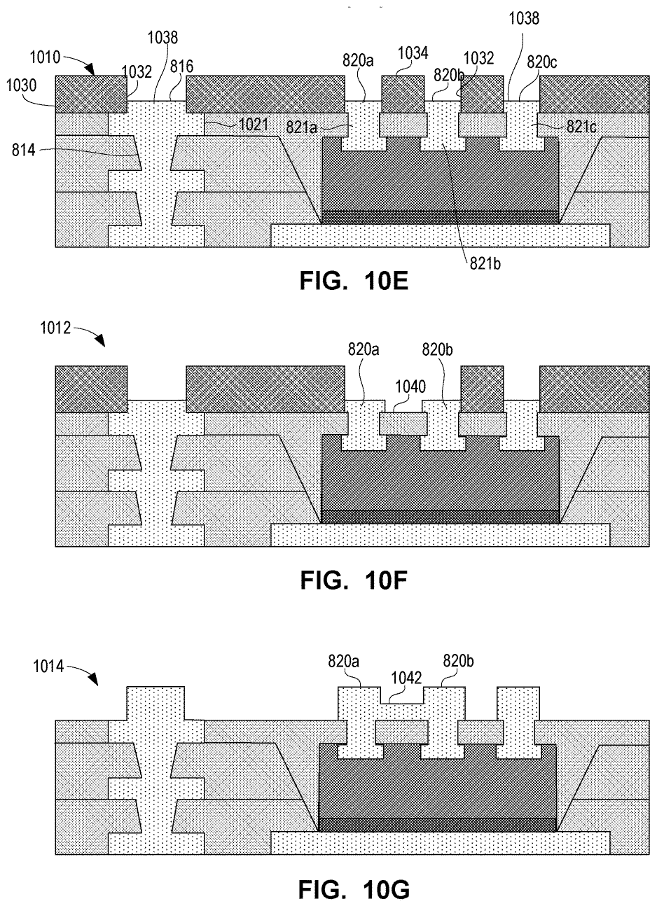

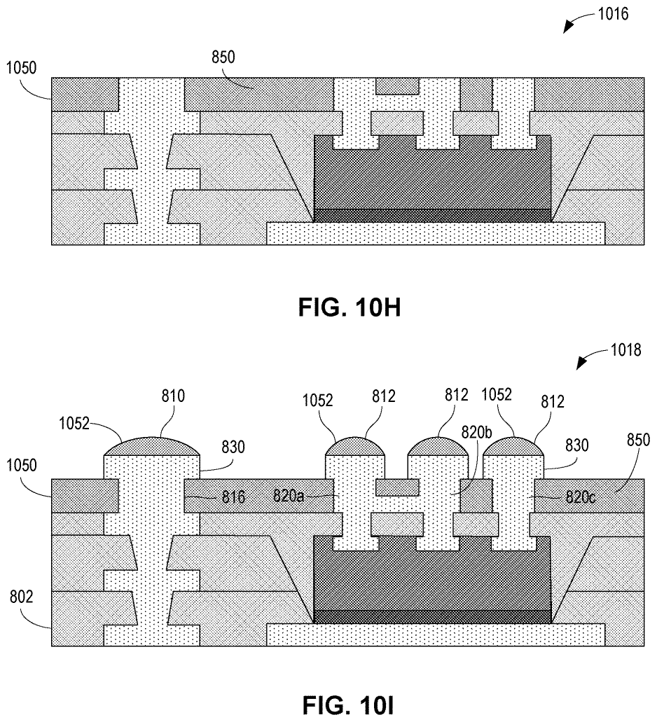

FIG. 9 is a flowchart of an example method 900 of fabricating an example IC package (e.g., the IC package 800 of FIG. 8). To facilitate discussion of the example method 900, the example method 900 is described in connection with the example IC package 800 of FIG. 8. For example, FIGS. 10A-10I are cross-sectional schematic illustrations of the example IC package 800 of FIG. 8 at various manufacturing stages 1002, 1004, 1006, 1008, 1010, 1012, 1014, 1016, 1018 corresponding to the example method 900 of FIG. 9. While an example manner of fabricating the example package substrate 802 has been illustrated in FIGS. 9 and 10A-10I, one or more of the operations and/or processes illustrated in FIGS. 9 and 10A-10I may be combined, divided, re-arranged, omitted, eliminated and/or implemented in any other way. Further still, the example methods of FIGS. 9 and 10A-10I may include processes and/or operations in addition to, or instead of, those illustrated in FIGS. 9 and 10A-10I and/or may include more than one of any or all of the illustrated processes and/or operations. In some examples, some or all of the operations outlined in the example method of FIG. 9 are performed automatically by fabrication equipment that is programmed to perform the operations.

At block 902, an example package substrate with a cavity is obtained. Referring to FIG. 10A the package substrate 802 is provided. The package substrate 802 includes a cavity 1020 and the conductive layer 920 is exposed within the cavity 1020. The package substrate 802 includes the conductive via 814 provided by any semiconductor manufacturing process(es). The cavity 1020 can be formed via lithography, laser, and/or any other suitable semiconductor fabrication technique(s). The conductive via 814 is provided with a landing pad 1021.

At block 904, an example interconnect bridge is provided. Referring to FIG. 10B, the interconnect bridge 804 is provided with pillars 821a-c coupled to the contact pads 818a-c. The pillars 821a-c extend or protrude away from an upper surface 1023 of the interconnect bridge 804. The adhesive layer 824 is provided opposite the pillars 821a-c. For example, the interconnect bridge 804 is fabricated separately from the package substrate 802 of block 902 and/or FIG. 10A. The interconnect bridge 804 is positioned in the cavity 1020. The adhesive layer 824 couples to the package substrate 802. As noted above, in some examples, the layers 824 and 826 can be an array of connected bumps/contact pads.

At block 906, the package substrate and the interconnect bridge is encapsulated. Referring to FIG. 10C, the package substrate 802 and the interconnect bridge 804 are encapsulated with an encapsulation layer 1026. For example, the encapsulation layer 1026 is molded onto the package substrate 802. The encapsulation layer 1026 can be provided by a liquid or semi-solid molding compound that is applied to the package substrate 802 and cured to develop a solid encapsulation layer that mechanically integrates with the package substrate 802. Subsequently, the encapsulation layer 1026 can be grinded using a grinding process to smooth the encapsulation layer 1026.

At block 908, one or more features are provided. Referring to FIGS. 10D-10F, the features are provided using a zero misalignment vertical approach (e.g., a ZMV approach). As used herein, zero misalignment vertical approach employs greyscale (e.g., a two-step) lithography process to vertically align or overlay the pillars 820a-c and the pillars 821a-c).

For example, referring to FIG. 10D, a photoresist layer 1030 is provided on the encapsulation layer 1026. After, openings or cavities 1032 are formed for the pillars 816 and 820a-c. Specifically, the cavities 1032 align (e.g., vertically align with respective ones of the pillars 821a-c, and the landing pad 1021 of the conductive via 814. For example, referring to FIG. 10D, the photoresist layer 1030 is provided and patterned on the encapsulation layer 1026. To develop a desired pattern of the features, the photoresist layer 1030 is exposed to light (e.g., ultraviolet (UV) light) through a mask. In this example, the desired pattern is used to provide the cavities 1032 aligned with or in communication with (e.g., vertically aligned with) respective pillars 821a-c of the first level interconnects 812 (FIG. 8) and the landing pad 1021 of the conductive via 814 of the package substrate 802. As shown in FIG. 10D, a portion 1034 of the photoresist layer 1030 between the first pillar 821a and the second pillar 821b is applied with a different light intensity to make the portion 1034 of the photoresist more soluble compared to other portions of the photoresist layer 1030 that remain in the illustrated example, but less soluble than the portions of the photoresist layer 1030 that have already been removed to define the cavities 1032.

Referring to FIG. 10E, to provide the features, the cavities 1032 are provided with conductive material 1038. For example, the conductive material 1038 is deposited in the cavities 1032 via an electroplating process. For example, the conductive material 1038 is electrochemically grown within the cavities using, for example, a sulfate solution (e.g., a copper sulfate solution). The plating process provides the pillars 816 and 820a-c that have straight-wall profiles. The pillar 816 electrically couples with the landing pad 1021 of the conductive via 814 and the pillars 820a-820c electrically couple with respective ones of the pillars 821a-821c.

Referring to FIG. 10F, after the cavities 1032 are provided with the conductive material 1038, the portion 1034 of the photoresist layer 1030 between the first pillar 820a and the second pillar 820b is removed to provide a trench 1040 therebetween.

At block 910, a conductive material is provided in the cavities to provide the features. For example, referring to FIG. 10G, a conductive material 1042 is provided in the trench 1040 between the first pillar 820a and the second pillar 820b. For example, the conductive material 1042 is provided where the portion 1034 of the photoresist layer 1030 was removed. In this manner, the conductive material 1042 provides the trace 822 electrically coupling the first pillar 820a and the second pillar 820b.

At block 912, a die encapsulation (DE) mold layer and grind processes are provided. Referring to FIG. 10H, in the DE mold process, the package substrate 802 and the interconnect bridge 804 are embedded or encapsulated in a mold compound 1050 to provide the encapsulation layer 850, which provides mechanical protection and structural support. The mold compound 1050 protects delicate interconnects and creates a uniform surface. The mold compound 1050 can be polyimide or any other epoxy-based material(s). After molding, a grinding process (e.g., using an abrasive wheel) is performed to mechanically remove material to achieve the required thickness, flatness, and/or coplanarity.

At block 914, first level interconnects are provided. Referring to FIG. 10I, the first level interconnects are provided. For example, the first level interconnects 810, 812 are provided by a lithography and first level interconnect (FLI) plating process. For example, the package substrate 802 (e.g., an upper surface of the mold compound 1050) is cleaned and typically coated with a thin conductive seed layer, such as copper, which enables subsequent electroplating. A photoresist layer is then applied over the seeded surface and patterned using lithography to define the first level interconnect layout relative to (e.g., in vertical alignment or overlayed with) the pillars 816 and 820a-c. The patterned resist creates openings that expose selected regions of the seed layer where new conductive features (e.g., the first level interconnects 810, 812) are intended to form, often aligning to or redistributing connections from the underlying surface pads 830 (e.g., coupled to the pillars 816, 820a-c). Electroplating is then performed, depositing metal—commonly copper—into the lithographically defined openings, growing the first level interconnect structures vertically and laterally until the desired thickness is reached. After plating, the photoresist is stripped, and any exposed seed layer in non-plated areas is removed by etching, electrically isolating the plated features. The resulting features provide the first level interconnects 810, 812 with the metal coating 1052 (e.g., a tin (Sn) coating).

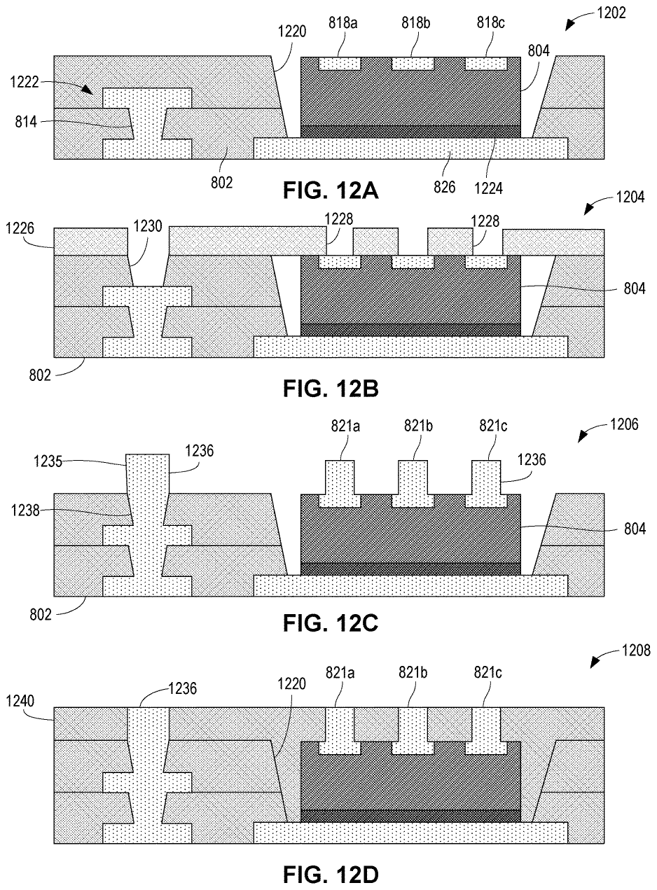

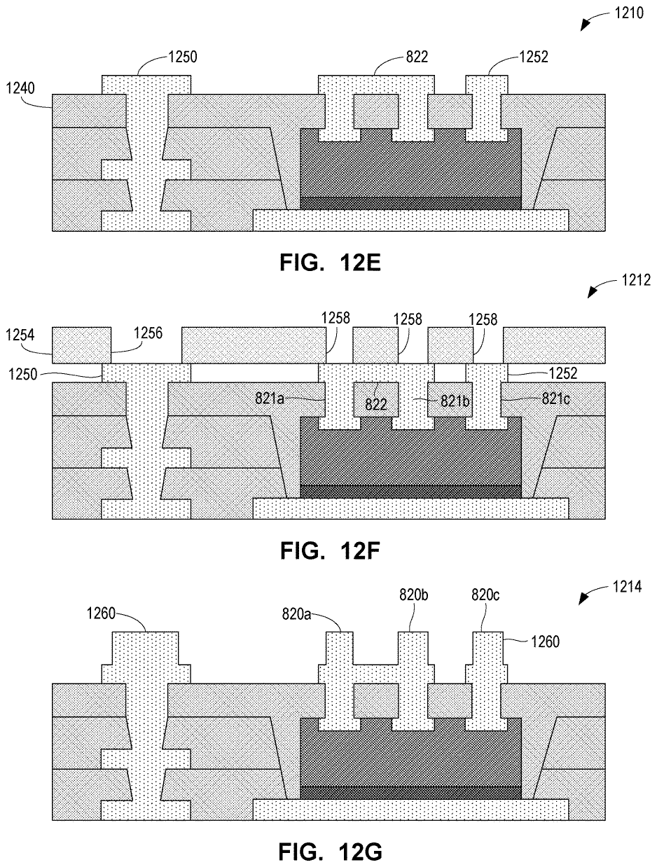

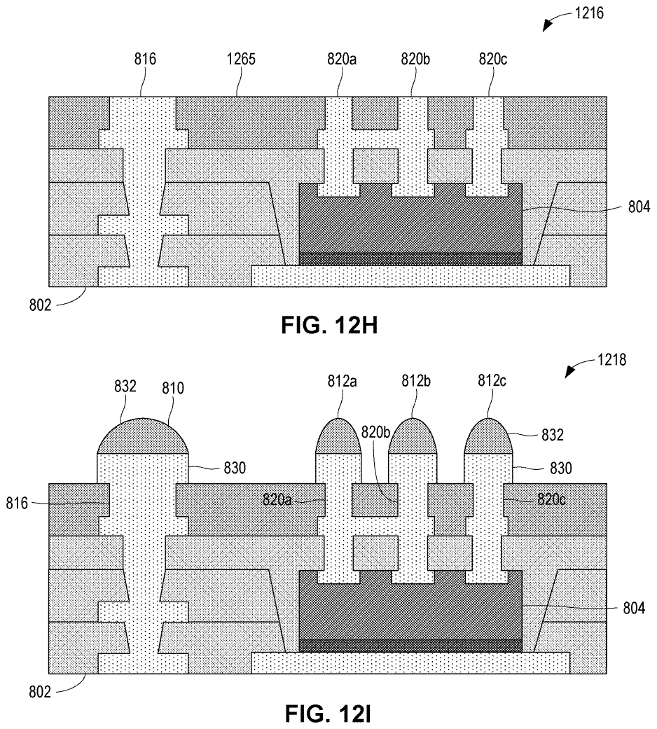

FIG. 11 is a flowchart of an example method 1100 of fabricating an example IC package (e.g., the IC package 800 of FIG. 8). To facilitate discussion of the example method 1100, the example method 1100 is described in connection with the example IC package 800 of FIG. 8. For example, FIGS. 12A-12I are cross-sectional schematic illustrations of the example IC package 800 of FIG. 8 at various manufacturing stages 1202, 1204, 1206, 1208, 1210, 1212, 1214, 1216, 1218 corresponding to the example method 1100 of FIG. 11. While an example manner of fabricating the example package substrate 802 has been illustrated in FIGS. 11 and 12A-12I, one or more of the operations and/or processes illustrated in FIGS. 11 and 12A-12I may be combined, divided, re-arranged, omitted, eliminated and/or implemented in any other way. Further still, the example methods of FIGS. 11 and 12A-12I may include processes and/or operations in addition to, or instead of, those illustrated in FIGS. 11 and 12A-12I and/or may include more than one of any or all of the illustrated processes and/or operations. In some examples, some or all of the operations outlined in the example method of FIG. 11 are performed automatically by fabrication equipment that is programmed to perform the operations.

The method 1100 begins at block 1102 by obtaining an example package substrate an example interconnect bridge. Referring to FIG. 12A, the package substrate 802 is provided with a cavity 1220 and the interconnect bridge 804 is coupled to the conductive layer 826 exposed by the cavity 1220. The package substrate 802 includes a portion 1222 of the conductive via 814 that is provided by any semiconductor manufacturing process(es). The cavity 805 can be formed via lithography, laser, and/or any other suitable semiconductor fabrication technique(s). The interconnect bridge 804 of the illustrated example is provided with the contact pads 818a-c and an adhesive layer 1224 opposite the contact pads 818a-c. For example, the interconnect bridge 804 is fabricated separately from the package substrate 802.

At block 1104, the interconnect bridge is coupled with the package substrate. For example, referring to FIG. 12A, the interconnect bridge 804 is positioned in the cavity 1220. The adhesive layer 1224 couples to the conductive layer 826 (e.g., a metal pad)).

At block 1106, one or more first features are patterned. For example, the pillars 821a-c are provided with the interconnect bridge 804. Additionally, a second portion 1238 of the conductive via 814 can be provided with the package substrate 802 (e.g., if needed). Referring to FIG. 12B, to provide the pillars 821a-c and the second portion 1238 of the conductive via 814, a photoresist layer 1226 is provided on the package substrate 802. A core via opening 1230 corresponding to the conductive via 814 is formed in the photoresist layer 1226 (e.g., in alignment with the first portion of the conductive via 814) and pillar openings 1228 are formed in the photoresist layer 1226 (e.g., in alignment with the contact pads 818a-c). The cover via opening 1230 and the pillar openings 1228 are formed via photolithography. In some examples, the cover via opening 1230 and the pillar openings 1228 are provided via etching and/or any other process(es). Referring to FIG. 12C, a conductive layer 1236 is provided in the core via opening 1230 and the pillar openings 1228. For example, the conductive layer 1236 is provided via an electroless (Eless) plating process(es). Electroless plating is a chemical process used to deposit a conductive layer onto a substrate without the need for electric current. The photoresist layer 1226 is removed. As a result, the pillars 821a-c are coupled to the contact pads 818a-c and extend or protrude away from the interconnect bridge 804. Additionally, a second portion 1238 of the conductive via 814 is provided along with a pillar 1235.

At block 1108, the package substrate and the interconnect bridge is encapsulated. Referring to FIG. 12D, the package substrate 802 and the interconnect bridge 804 are encapsulated with an encapsulation layer 1240. For example, the encapsulation layer 1240 is molded onto the package substrate 802. The encapsulation layer 1240 can be provided by a liquid or semi-solid molding compound that is applied to the package substrate 802 and cured to develop a solid encapsulation layer that mechanically integrates with the package substrate 802. Subsequently, the encapsulation layer 1240 can be grinded using a grinding process to smooth the encapsulation layer 1240. The encapsulation material encases or surrounds the pillars 821a-c, the pillar 1235, and fills the cavity 1220.

At block 1110, one or more second features are provided. For example, the one or more second features are provided via lithography (e.g., a surface metal routing layer). For example, referring to FIG. 12E-12G, the pillars 816 and 820a-c are provided via lithography. Referring to FIG. 12E, a core pad 1250, a bump pad 1252, and the trace 822 are provided on the encapsulation layer 1240. In some examples, the core pad 1250, the bump pad 1252 and the trace 822 are provided by adding a photoresist layer, patterning the photoresist layer to form openings corresponding to the core pad 1250 and the bump pad 1252, and a trench corresponding on the trace 822, and filling the openings and trench with conductive material via electroplating process.

Referring to FIG. 12F, another photoresist layer 1254 is provided on the core pad 1250, the bump pad 1252 and the trace 822 and patterned. For example, the pattern in the photoresist layer 1254 includes openings 1256 and 1258 in alignment with the respective ones of the core pad 1250, the pillars 821a-b, and the bump pad 1252 (e.g., the pillar 821c).

Referring to FIGS. 12F and 12G, after the pattern is created, a seed layer of metal 1260, typically copper, is deposited through methods like sputtering to establish a foundation for bump plating. Next, bump plating is executed, wherein a thicker layer of solder or other materials is electroplated onto the seed layer to create the pillars 816, 820a-820c (e.g., bump pads). This process allows for the precise formation of adequately sized bumps necessary for effective electrical connections in flip-chip packaging. During this process, die flatness reference (DFR) strips can be employed to maintain alignment and flatness. These reference strips help form the bump pads accurately and consistently across the surface. Ultimately, the integration of bump plating with DFR strips enhances the manufacturing process, resulting in reliable, high-performance semiconductor devices ready for assembly onto circuit boards and other applications.

At block 1112, a die encapsulation (DE) mold and grind processes are provided. Referring to FIG. 12H, in the DE mold process, the package substrate 802 and the interconnect bridge 804 are embedded or encapsulated in a mold compound 1265 to provide mechanical protection and structural support. The mold compound 1265 protects delicate interconnects and creates a uniform surface. The mold compound 1265 can be polyimide or any other epoxy-based material(s). After molding, a grinding process (e.g., using an abrasive wheel) is performed to mechanically remove material to achieve the required thickness, flatness, and/or coplanarity.

At block 1114, first level interconnects are provided. Referring to FIG. 12I, the first level interconnects are provided. For example, the first level interconnects 810, 812a-c are provided by a lithography and first level interconnect (FLI) plating process. For example, the package substrate 802 (e.g., a surface of the mold compound 1265) is cleaned and typically coated with a thin conductive seed layer, such as copper, which enables subsequent electroplating. A photoresist layer is then applied over the seeded surface and patterned using lithography to define the first level interconnect layout relative to (e.g., in vertical alignment or overlayed with) the pillars 816 and 820a-c. The patterned resist creates openings that expose selected regions of the seed layer where new conductive features (e.g., the first level interconnects 810, 812a-c) are intended to form, often aligning to or redistributing connections from the underlying pads (e.g., the pillars 816, 820a-c). Electroplating is then performed, depositing metal—commonly copper—into the lithographically defined openings, growing the first level interconnect structures vertically and laterally until the desired thickness is reached. After plating, the photoresist is stripped, and any exposed seed layer in non-plated areas is removed by etching, electrically isolating the plated features. The resulting features provide the first level interconnects 810, 812a-c with the metal material 832 (e.g., a tin (Sn) coating).

FIG. 13 is a cross-sectional view of another IC package 1300 disclosed herein. The IC package 1300 of the illustrated example includes a package substrate 1302 and an interconnect bridge 1304. The package substrate 1302 and the interconnect bridge 1304 can implement the example package substrate 110 and the interconnect bridge 128 of FIG. 1. The package substrate 1302 of the illustrated example includes a core layer 1306, a dielectric layer 1308, a mold layer 1310, and a dielectric layer 1312. The mold layer 1310 is between (e.g., layered directly between) the dielectric layer 1308 and the dielectric layer 1312. The mold layer 1310 can be polyimide, ABF, an epoxy, and/or any other dielectric material(s). The dielectric layer 1312 can be solder resist, ABF and/or any other dielectric material(s).

Additionally, the mold layer 1310 is positioned between the interconnect bridge 1304 and the package substrate 1302. The dielectric layer 1308 is between the mold layer 1310 and the core layer 1306. Additionally, the IC package 1300 includes first level interconnects (FLIs) 1314 (e.g., core bumps) to couple with core bumps of a die (e.g., the core bumps 116 of the die 108 of FIG. 1) and first level interconnects (FLIs) 1316 to couple with bridge bumps of the die (e.g., the bridge bumps 118 of the die 108 of FIG. 1). The IC package substrate 1302 includes a plurality of conductive vias 1318 to electrically couple to respective ones of the FLIs 1314 and a plurality of conductive vias 1320 to electrically couple to respective ones of the FLIs 1316. The FLIs 1316 have a bump pitch that is less than 25 micrometers (e.g., 10 micrometers, 15 micrometers, 16 micrometers, etc.). However, in some examples, the bump pitch can be equal to or greater than 25 micrometers. The FLIs 1314 and 1316 are each plated with a metal material or solder bump 1322 (e.g., tin (Sn)).

The interconnect bridge 1304 includes one or more pillars 1324. The pillars 1324 protrude from a first surface 1326 of the interconnect bridge 1304. Each pillar 1324 provides a respective one of the FLIs 1316. The pillars 1324 are plated with a conductive material (e.g., copper). In some examples, the pillars 1324 can have a bump pitch that is less than 25 micrometers (μm) (e.g., 10 μm, 15 μm, 16 μm, etc.) or greater than 25 micrometers (μm). The pillars 1324 have a substantially straight profile. The pillars 1324 have a straight-wall (e.g., a non-conical) profile (e.g., in a vertical direction in the orientation of FIG. 13).

Additionally, the interconnect bridge 1304 includes contact pads 1330 that couple to respective conductive vias 1332 of the package substrate 1302. The contact pads 1330 are formed with the interconnect bridge 1304, like the pillars 1324, prior to attachment of the interconnect bridge 1304 with the package substrate 1302. The contact pads 1330 and the pillars 1324 provide an electrical coupling between the interconnect bridge 1304 and the package substrate 1302 (by way of a TSV extending therebetween through the interconnect bridge 1304), providing a direct path for power delivery and/or signal transmission.

Additionally, the pillars 1324 and the contact pads 1330 are an integral part of the interconnect bridge 1304 (i.e., the EMIB-T die). In other words, the pillars 1324 and the contact pads 1330 are with the interconnect bridge 1304 prior to attachment with the package substrate 1302. In other words, the interconnect bridge 1304 of the illustrated example is prefabricated or pre-formed with the pillars 1324 (e.g., pre-formed pillars, copper plated pillars) and the contact pads 1330. Additionally, to secure or protect the pillars 1324, the interconnect bridge 1304 includes a protective layer 1340 (e.g., an epoxy material, polyimide, etc.) that encases or surrounds the pillars 1324. In some examples, the protective layer 1340 is composed of a different material from the mold layer 1310. Pre-forming the interconnect bridge 1304 prior to coupling with the package substrate 1302 enables achievement of pitch scaling that is less than 25 micrometers (μm). Additionally or alternatively, providing the pillars 1324 with the formation of the interconnect bridge 1304 eliminates or reduces overlay alignment offset issues that may otherwise have occurred during a build-up process (e.g., when bump pitch is less than 25 micrometers). The IC package 1300 of the illustrated example improves reliability, reduces manufacturing costs, and enhances competitiveness compared to alternative interconnect solutions.

The example IC package 1300 of the illustrated example employs an alternative fabrication method and architecture for interconnect bridges to address challenges associated with alignment, die shift, and via reliability concerns (e.g., critical dimensions). Generally, an encapsulation via is fabricated with the interconnect bridge, which is in contrast to current POR process flow where an encapsulation bridge via is fabricated as part of the package substrate. In this manner, a bridge via CD can be enlarged compared to the current POR process. Once the interconnect bridge is bonded, a dielectric is laminated or molded followed by grinding to reveal metal (e.g., Cu). With the bridge via already fabricated and revealed, core vias are then laser drilled. The encapsulation layer is completed by this operation. After encapsulation formation, multiple lithography operations or loops are applied to fabricate surface routing, insulator and FLI layers. This process is distinct from current process flows where solder resist openings are typically drilled with a laser process. This approach replaces solder resist with polyimide to allow for an all lithography method to provide the surface routing layer and upward. This all-lithography approach allows for much better overlay performance.

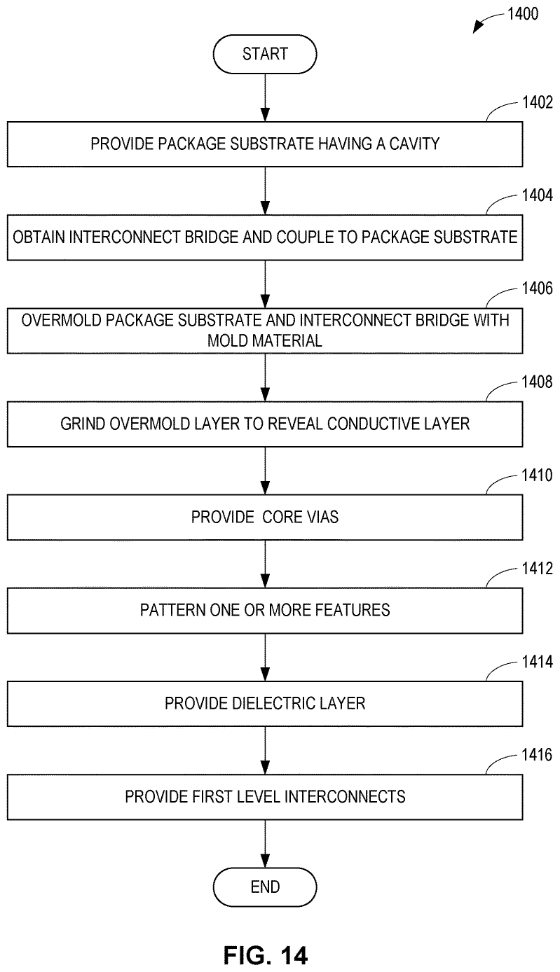

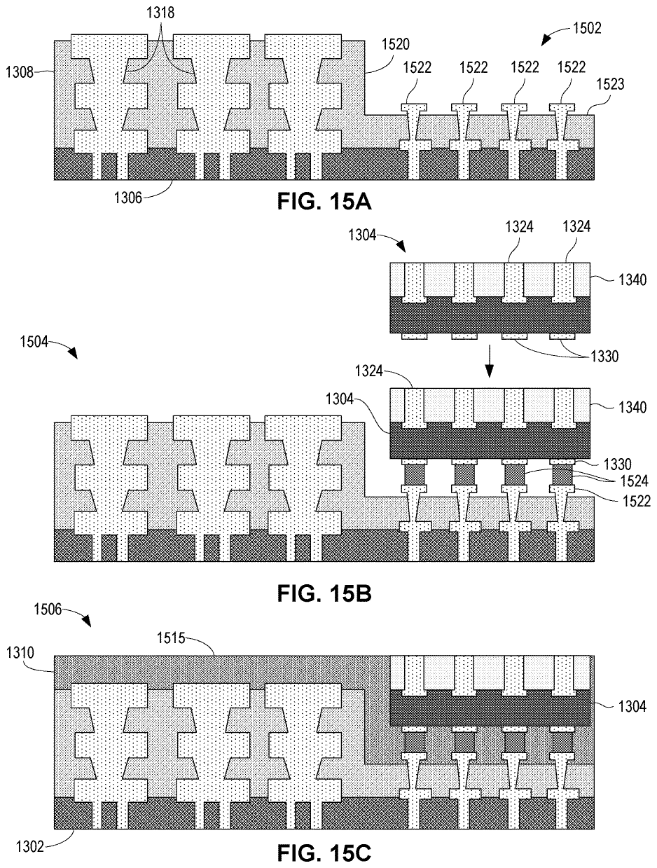

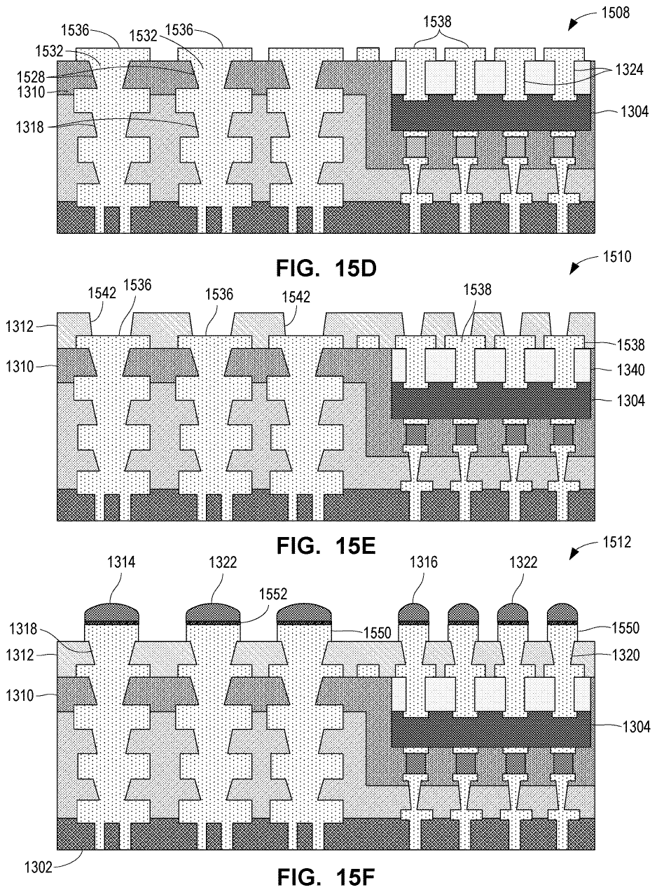

FIG. 14 is a flowchart of an example method 1400 of fabricating an example IC package (e.g., the IC package 1300 of FIG. 13). To facilitate discussion of the example method 1300, the example method 1400 is described in connection with the example IC package 1300 of FIG. 13. For example, FIGS. 15A-15F are cross-sectional schematic illustrations of the example IC package 1300 of FIG. 13 at various manufacturing stages 1502, 1504, 1506, 1508, 1510, 1512, corresponding to the example method 1400 of FIG. 14. While an example manner of fabricating the example package substrate 1302 has been illustrated in FIGS. 14 and 15A-15F, one or more of the operations and/or processes illustrated in FIGS. 14 and 15A-15F may be combined, divided, re-arranged, omitted, eliminated and/or implemented in any other way. Further still, the example methods of FIGS. 14 and 15A-15F may include processes and/or operations in addition to, or instead of, those illustrated in FIGS. 13 and 15A-15F and/or may include more than one of any or all of the illustrated processes and/or operations. In some examples, some or all of the operations outlined in the example method of FIG. 14 are performed automatically by fabrication equipment that is programmed to perform the operations.

At block 1402, an example package substrate with an example cavity is provided. Referring to FIG. 15A, the package substrate 1302 including the core layer 1306, the dielectric layer 1308, and the conductive vias 1318 are provided by semiconductor manufacturing process(es). A cavity 1520 is provided in the package substrate 1302 to receive the interconnect bridge 1304. The cavity 1520 includes one or more of landing pads 1522 adjacent a bottom surface 1523 of the cavity 1520. The cavity 1520 can be formed by, for example, photolithography, mechanical drilling, laser drilling, dry etching, and/or any other suitable semiconductor manufacturing process(es).

At block 1404, an example interconnect bridge is provided and coupled to the package substate (e.g., via thermal compression bonding). Referring to FIG. 15B, the interconnect bridge 1304 is obtained and coupled to the package substrate 1302. The interconnect bridge 1304 is prefabricated with the pillars 1324 and the contact pads 1330. The interconnect bridge 1304 also includes the protective layer 1340. The pillars 1324 and the contact pads 1330 of the interconnect bridge 1304 are prefabricated by an independent wafer fabrication stage and remain intact throughout subsequent processing steps. Thus, the interconnect bridge 1304 is a prefabricated structure that is separate than the package substrate 1302. Referring still to FIG. 15B, to couple the interconnect bridge 1304 and the package substrate 1302, the contact pads 1330 of the interconnect bridge 1304 are coupled (e.g., soldered) with respective ones of the landing pads 1522 within the cavity 1520. In this example, a solder material or pads 1524 (e.g., tin (Sn)) is provided between the landing pads 1522 and the contact pads 1330 to improve bonding. For example, the interconnect bridge 1304 is coupled to the package substrate 1302 via thermal compression bonding manufacturing.

At block 1406, the package substrate and the interconnect bridge are overmolded or laminated with an example dielectric material. Referring to FIG. 15C, the package substrate 1302 and the interconnect bridge 1304 are overmolded with the mold material 1515 to provide the mold layer 1310. The mold layer 1310 is provided on the package substrate 1302 and underneath the interconnect bridge 1304 to enclose or encase the contact pads 1330 and the landing pads 1522. Thus, the mold material 1515 fills an area beneath the interconnect bridge 1304 such that the mold material 1515 is positioned between the package substrate 1302 and the interconnect bridge 1304. In other words, the mold material 1515 is a fill material that is provided underneath the interconnect bridge 1304 and fills the cavity 1520.

At block 1408, the overmolded layer is grinded to reveal the pillars. For example, referring to FIG. 15C, the mold layer 1310 is grinded via a grinding process (e.g., a grinding wheel) to reveal ends of the pillars 1324.

At block 1410, example core via openings are provided. Referring to FIG. 15D, via openings 1528 are provided in the mold layer 1310 corresponding to respective ones of the conductive vias 1318 and filled with a conductive material 1532 to provide portions 1534 of the conductive vias 1318.

At block 1412, one or more features are pattered. For example, referring to FIG. 15D, surface routing and contacts are provided via lithography. In this example, one or more contact pads 1536 are provided on the portions 1534 of the conductive vias 1318 and contact pads 1538 are provided on the pillars 1324. The contact pads 1536 and 1538 are provided via lithography and electroplating manufacturing techniques. For example, a photoresist layer is added to the package substrate 1302 and the interconnect bridge 1304, the photoresist layer is patterned to form openings corresponding to the contact pads 1536 and 1538, and the openings are filled with conductive material via electroplating process to provide the contact pads 1536, 1538.

At block 1414, an example dielectric layer is provided. Referring to FIG. 15E, the dielectric layer 1312 is provided over the contact pads 1536 and 1538 and on the mold layer 1310 and the protective layer 1340 of the interconnect bridge 1304. In some examples, the dielectric layer 1312 can be provided by a lamination process. Subsequently, via openings 1542 are provided in the dielectric layer 1312. For example, the via openings 1542 can be formed by a laser, photolithography, and/or any other manufacturing process(es). The via openings 1542 correspond to respective ones of the contact pads 1536 and 1538. The via openings 1542 are subsequently filled with a conductive material to provide portions of the conductive vias 1318 and 1320 (FIG. 15F).

At block 1416, example first level interconnects are provided. Referring to FIG. 15F, the FLIs 1314, 1316 are provided. For example, the FLIs 1314, 1316 are provided by a lithography and first level interconnect (FLI) plating process. For example, the package substrate 1302 (e.g., the dielectric layer 1312) is cleaned and typically coated with a thin conductive seed layer, such as copper, which enables subsequent electroplating. A photoresist layer is then applied over the seeded surface and patterned using lithography to define the first level interconnect layout relative to (e.g., in vertical alignment or overlayed with) the conductive vias 1318 and 1320. The patterned resist creates openings that expose selected regions of the seed layer where new conductive features (e.g., the first level interconnects 1314, 1316) are intended to form, often aligning to or redistributing connections from the underlying pads (e.g., the first level interconnects 1314, 1316). Electroplating is then performed, depositing metal—commonly copper—into the lithographically defined openings, growing the first level interconnect structures vertically and laterally until the desired thickness is reached. After plating, the photoresist is stripped, and any exposed seed layer in non-plated areas is removed by etching, electrically isolating the plated features. The resulting features provide the FLIs 1314, 1316. The FLIs 1314, 1316 include surface pads 1550 on the dielectric layer 1312 having a diffusion layer 1552 and the solder bump 1322 (e.g., a tin (Sn) coating).

Employing a dual lithography process, surface pads 1550, the diffusion layer 1552 and the solder bump 1322 (e.g., a metal layer, tin (Sn) plating) can be provided on the FLIs 1314, 1316. For example, the diffusion layer 1552 can be a thin seed/wettable layer provided on the surface pads 1550, and the solder bump 1322 can be a thicker solder-forming layer provided on the diffusion layer 1552. The diffusion layer 1552 improves adhesion or solderability and the solder bump 1322 can be employed for bonding/interconnect formation.

Although each example IC package 100, 200, 500, 800, 1300 and/or other components of the IC package 100, 200, 500, 800, 1300 disclosed above have certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features. For example, the interconnect bridge 504 of FIG. 5 and/or the interconnect bridge 804 of FIG. 8 can include contact pads (e.g., the contact pad 241 of FIG. 2, the contact pads 1330 of the interconnect bridge 1304 of FIG. 13) and the metal pad 521 and/or the conductive layer 826 can include interconnect landing pads (e.g., the landing pads 1522 within the cavity 1520), where the contact pads electrically couple (e.g., solder) with respective ones of the landing pads. In some such examples, the interconnect bridge 504, 804 can include a TSV (e.g., the TSV 240 of FIG. 2). Likewise, the interconnect bridge 204 of FIG. 2 and/or the interconnect bridge 1304 of FIG. 13 can be replaced with the interconnect bridge 504 and/or the interconnect bridge 804 (e.g., an EMIB with an adhesive layer instead of the contact pads 1330). In other words, any example package substrate 110, 202, 502, 802, 1302 and/or interconnect bridge 128, 204, 504, 804, 1304 can be interchanged another one of the package substrate 110, 202, 502, 802, 1302 and/or interconnect bridge 128, 204, 504, 804, 1304.

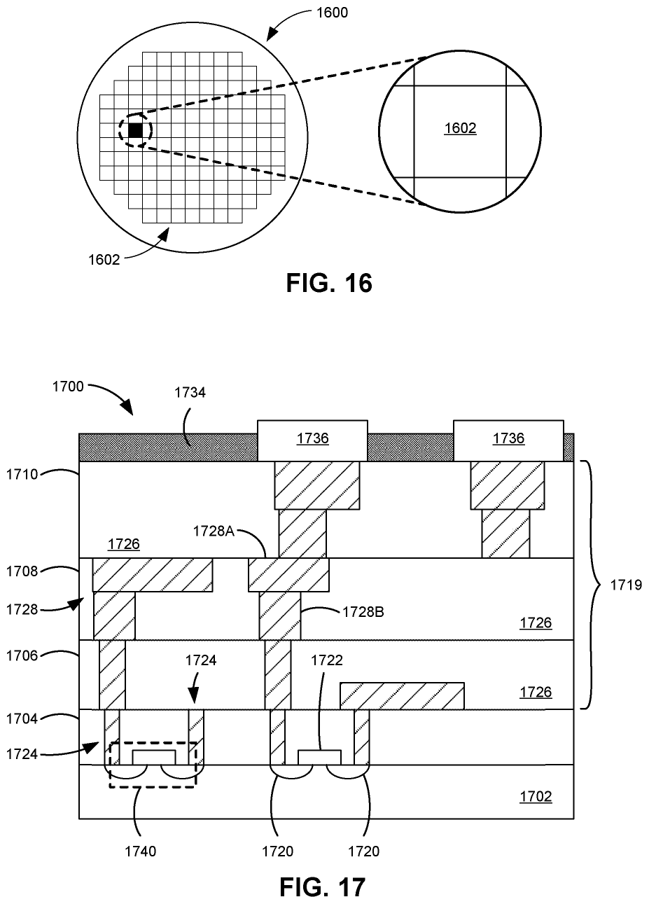

The example IC packages 100, 200, 500, 800, 1300, the example package substrates 110, 202, 502, 802, 1302, and/or the example interconnect bridges 128, 204, 504, 804, 1304 disclosed herein may be included in any suitable electronic component. FIGS. 16-20 illustrate various examples of apparatus that may include or be included in the IC packages 100, 200, 500, 800, 1300, the example package substrates 110, 202, 502, 802, 1302, and/or the example interconnect bridges 128, 204, 504, 804, 1304 disclosed herein.

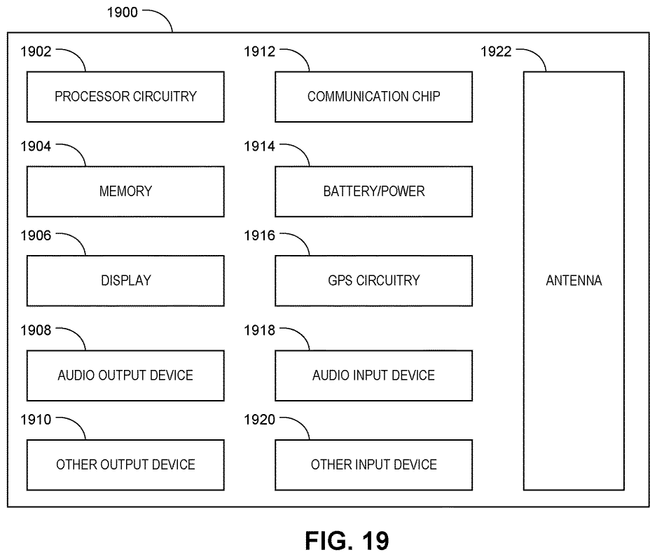

FIG. 16 is a top view of a wafer 1600 and dies 1602 that may be included in an IC package whose substrate includes one or more example package substrates 110, 202, 502, 802, 1302, and/or the example interconnect bridges 128, 204, 504, 804, 1304 in accordance with any of the examples disclosed herein. The wafer 1600 includes semiconductor material and one or more dies 1602 having circuitry. Each of the dies 1602 may be a repeating unit of a semiconductor product. After the fabrication of the semiconductor product is complete, the wafer 1600 may undergo a singulation process in which the dies 1602 are separated from one another to provide discrete “chips.” The die 1602 includes one or more transistors (e.g., some of the transistors 1740 of FIG. 17, discussed below), supporting circuitry to route electrical signals to the transistors, passive components (e.g., traces, resistors, capacitors, inductors, and/or other circuitry), and/or any other components. In some examples, the die 1602 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 1602. For example, a memory array of multiple memory circuits may be formed on a same die 1602 as programmable circuitry (e.g., the processor circuitry 1902 of FIG. 19) and/or other logic circuitry. Such memory may store information for use by the programmable circuitry. The example IC packages 100, 200, 500, 800, 1300 disclosed herein may be manufactured using a die-to-wafer assembly technique in which some dies are attached to a wafer 1600 that includes others of the dies, and the wafer 1600 is subsequently singulated.

FIG. 17 is a cross-sectional side view of an IC device 1700 that may be included in the example IC package 100, 200, 500, 800, 1300 (e.g., in any one of the dies 106, 108, 212). One or more of the IC devices 1700 may be included in one or more dies 1602 (FIG. 16). The IC device 1700 may be formed on a die substrate 1702 (e.g., the wafer 1600 of FIG. 16) and may be included in a die (e.g., the die 1602 of FIG. 16). The die substrate 1702 may be a semiconductor substrate including semiconductor materials including, for example, n-type or p-type materials systems (or a combination of both). The die substrate 1702 may include, for example, a crystalline substrate formed using a bulk silicon or a silicon-on-insulator (SOI) substructure. In some examples, the die substrate 1702 may be formed using alternative materials, which may or may not be combined with silicon, and which include but are not limited to germanium, indium antimonide, lead telluride, indium arsenide, indium phosphide, gallium arsenide, or gallium antimonide. Further materials classified as group II-VI, III-V, or IV may also be used to form the die substrate 1702. Although a few examples of materials from which the die substrate 1702 may be formed are described here, any material that may serve as a foundation for an IC device 1700 may be used. The die substrate 1702 may be part of a singulated die (e.g., the dies 1602 of FIG. 16) or a wafer (e.g., the wafer 1600 of FIG. 16).

The IC device 1700 may include one or more device layers 1704 disposed on and/or above the die substrate 1702. The device layer 1704 may include features of one or more transistors 1740 (e.g., metal oxide semiconductor field-effect transistors (MOSFETs)) formed on the die substrate 1702. The device layer 1704 may include, for example, one or more source and/or drain (S/D) regions 1720, a gate 1722 to control current flow between the S/D regions 1720, and one or more S/D contacts 1724 to route electrical signals to/from the S/D regions 1720. The transistors 1740 may include additional features not depicted for the sake of clarity, such as device isolation regions, gate contacts, and the like. The transistors 1740 are not limited to the type and configuration depicted in FIG. 17 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1740 may include a gate 1722 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1740 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1740 along the source-channel-drain direction, the gate electrode may include a U-shaped structure that includes a bottom portion substantially parallel to the surface of the die substrate 1702 and two sidewall portions that are substantially perpendicular to the top surface of the die substrate 1702. In other examples, at least one of the metal layers that form the gate electrode may be a planar layer that is substantially parallel to the top surface of the die substrate 1702 and does not include sidewall portions substantially perpendicular to the top surface of the die substrate 1702. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1720 may be formed within the die substrate 1702 adjacent to the gate 1722 of corresponding transistor(s) 1740. The S/D regions 1720 may be formed using an implantation/diffusion process or an etching/deposition process, for example. In the former process, dopants such as boron, aluminum, antimony, phosphorus, or arsenic may be ion-implanted into the die substrate 1702 to form the S/D regions 1720. An annealing process that activates the dopants and causes them to diffuse farther into the die substrate 1702 may follow the ion-implantation process. In the latter process, the die substrate 1702 may first be etched to form recesses at the locations of the S/D regions 1720. An epitaxial deposition process may then be carried out to fill the recesses with material that is used to fabricate the S/D regions 1720. In some implementations, the S/D regions 1720 may be fabricated using a silicon alloy such as silicon germanium or silicon carbide. In some examples, the epitaxially deposited silicon alloy may be doped in situ with dopants such as boron, arsenic, or phosphorus. In some examples, the S/D regions 1720 may be formed using one or more alternate semiconductor materials such as germanium or a group III-V material or alloy. In further examples, one or more layers of metal and/or metal alloys may be used to form the S/D regions 1720.

Electrical signals, such as power and/or input/output (I/O) signals, may be routed to and/or from the devices (e.g., transistors 1740) of the device layer 1704 through one or more interconnect layers disposed on the device layer 1704 (illustrated in FIG. 17 as interconnect layers 1706-1710). For example, electrically conductive features of the device layer 1704 (e.g., the gate 1722 and the S/D contacts 1724) may be electrically coupled with the interconnect structures 1728 of the interconnect layers 1706-1710. The one or more interconnect layers 1706-1710 may form a metallization stack (also referred to as an “ILD stack”) 1719 of the IC device 1700.

The interconnect structures 1728 may be arranged within the interconnect layers 1706-1710 to route electrical signals according to a wide variety of designs (in particular, the arrangement is not limited to the particular configuration of interconnect structures 1728 depicted in FIG. 17). Although a particular number of interconnect layers 1706-1710 is depicted in FIG. 17, examples of the present disclosure include IC devices having more or fewer interconnect layers than depicted.

In some examples, the interconnect structures 1728 may include lines 1728a and/or vias 1728b filled with an electrically conductive material such as a metal. The lines 1728a may be arranged to route electrical signals in a plane that is substantially parallel with a surface of the die substrate 1702 upon which the device layer 1704 is formed. For example, the lines 1728a may route electrical signals in and/or out of the page from the perspective of FIG. 17. The vias 1728b may be arranged to route electrical signals in a plane that is substantially perpendicular to the surface of the die substrate 1702 upon which the device layer 1704 is formed. In some examples, the vias 1728b may electrically couple lines 1728a of different interconnect layers 1706-1710 together.

The interconnect layers 1706-1710 may include a dielectric material 1726 disposed between the interconnect structures 1728, as shown in FIG. 17. In some examples, the dielectric material 1726 in different ones of the interconnect layers 1706-1710 may have different compositions; in other examples, the composition of the dielectric material 1726 between different interconnect layers 1706-1710 may be the same.

A first interconnect layer 1706 (referred to as Metal 1 or “M1”) may be formed directly on the device layer 1704. In some examples, the first interconnect layer 1706 may include lines 1728a and/or vias 1728b, as shown. The lines 1728a of the first interconnect layer 1706 may be coupled with contacts (e.g., the S/D contacts 1724) of the device layer 1704.

A second interconnect layer 1708 (referred to as Metal 2 or “M2”) may be formed directly on the first interconnect layer 1706. In some examples, the second interconnect layer 1708 may include vias 1728b to couple the lines 1728a of the second interconnect layer 1708 with the lines 1728a of the first interconnect layer 1706. Although the lines 1728a and the vias 1728b are structurally delineated with a line within each interconnect layer (e.g., within the second interconnect layer 1708) for the sake of clarity, the lines 1728a and the vias 1728b may be structurally and/or materially contiguous (e.g., simultaneously filled during a dual-damascene process) in some examples.

A third interconnect layer 1710 (referred to as Metal 3 or “M3”) (and additional interconnect layers, as desired) may be formed in succession on the second interconnect layer 1708 according to similar techniques and/or configurations described in connection with the second interconnect layer 1708 and/or the first interconnect layer 1706. In some examples, the interconnect layers that are “higher up” in the metallization stack 1719 in the IC device 1700 (i.e., further away from the device layer 1704) may be thicker.

The IC device 1700 may include a solder resist material 1734 (e.g., polyimide or similar material) and one or more conductive contacts 1736 formed on the interconnect layers 1706-1710. In FIG. 17, the conductive contacts 1736 are illustrated as taking the form of bond pads. The conductive contacts 1736 may be electrically coupled with the interconnect structures 1728 and configured to route the electrical signals of the transistor(s) 1740 to other external devices. For example, solder bonds may be formed on the one or more conductive contacts 1736 to mechanically and/or conductively/electrically couple a chip including the IC device 1700 with another component (e.g., a circuit board). The IC device 1700 may include additional or alternate structures to route the electrical signals from the interconnect layers 1706-1710; for example, the conductive contacts 1736 may include other analogous features (e.g., posts) that route the electrical signals to external components.

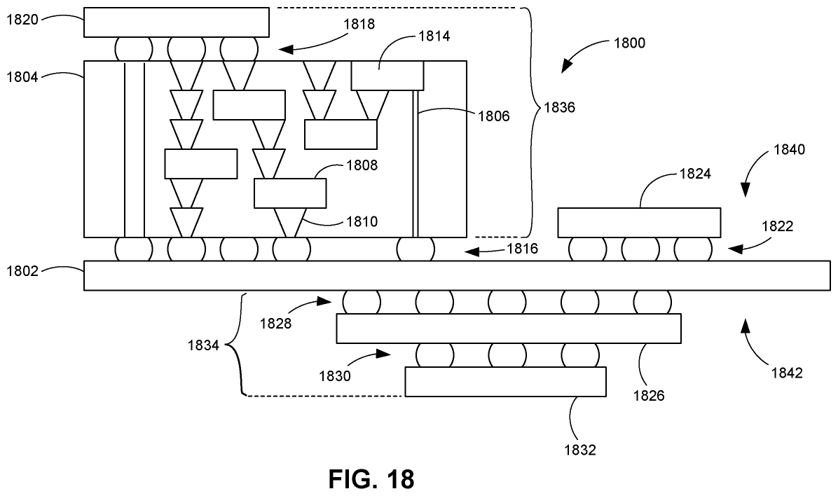

FIG. 18 is a cross-sectional side view of an IC device assembly 1800 that may include the IC packages 100, 200, 500, 800, 1300 disclosed herein. In some examples, the IC device assembly corresponds to the IC packages 100, 200, 500, 800, 1300. The IC device assembly 1800 includes a number of components disposed on a circuit board 1802 (which may be, for example, a motherboard). The IC device assembly 1800 includes components disposed on a first face 1840 of the circuit board 1802 and an opposing second face 1842 of the circuit board 1802; generally, components may be disposed on one or both faces 1840 and 1842.

In some examples, the circuit board 1802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1802. In other examples, the circuit board 1802 may be a non-PCB substrate.

The IC device assembly 1800. illustrated in FIG. 18. includes a package-on-interposer structure 1836 coupled to the first face 1840 of the circuit board 1802 by coupling components 1816. The coupling components 1816 may electrically and mechanically couple the package-on-interposer structure 1836 to the circuit board 1802, and may include solder balls (as shown in FIG. 18), male and female portions of a socket, an adhesive, an underfill material, and/or any other suitable electrical and/or mechanical coupling structure.

The package-on-interposer structure 1836 may include an IC package 1820 coupled to an interposer 1804 by coupling components 1818. The coupling components 1818 may take any suitable form for the application, such as the forms discussed above with reference to the coupling components 1816. Although a single IC package 1820 is shown in FIG. 18, multiple IC packages may be coupled to the interposer 1804; indeed, additional interposers may be coupled to the interposer 1804. The interposer 1804 may provide an intervening substrate used to bridge the circuit board 1802 and the IC package 1820. The IC package 1820 may be or include, for example, a die (the die 1602 of FIG. 16), an IC device (e.g., the IC device 1700 of FIG. 17), or any other suitable component. Generally, the interposer 1804 may spread a connection to a wider pitch or reroute a connection to a different connection. For example, the interposer 1804 may couple the IC package 1820 (e.g., a die) to a set of BGA conductive contacts of the coupling components 1816 for coupling to the circuit board 1802. In the example illustrated in FIG. 18, the IC package 1820 and the circuit board 1802 are attached to opposing sides of the interposer 1804; in other examples, the IC package 1820 and the circuit board 1802 may be attached to the same side of the interposer 1804. In some examples, three or more components may be interconnected by way of the interposer 1804.

In some examples, the interposer 1804 may be formed as a PCB, including multiple metal layers separated from one another by layers of dielectric material and interconnected by electrically conductive vias. In some examples, the interposer 1804 may be formed of an epoxy resin, a fiberglass-reinforced epoxy resin, an epoxy resin with inorganic fillers, a ceramic material, or a polymer material such as polyimide. In some examples, the interposer 1804 may be formed of alternate rigid or flexible materials that may include the same materials described above for use in a semiconductor substrate, such as silicon, germanium, and other group III-V and group IV materials. The interposer 1804 may include metal interconnects 1808 and vias 1810, including but not limited to through-silicon vias (TSVs) 1806. The interposer 1804 may further include embedded devices 1814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1804. The package-on-interposer structure 1836 may take the form of any of the package-on-interposer structures known in the art.

The IC device assembly 1800 may include an IC package 1824 coupled to the first face 1840 of the circuit board 1802 by coupling components 1822. The coupling components 1822 may take the form of any of the examples discussed above with reference to the coupling components 1816, and the IC package 1824 may take the form of any of the examples discussed above with reference to the IC package 1820.

The IC device assembly 1800 illustrated in FIG. 18 includes a package-on-package structure 1834 coupled to the second face 1842 of the circuit board 1802 by coupling components 1828. The package-on-package structure 1834 may include a first IC package 1826 and a second IC package 1832 coupled together by coupling components 1830 such that the first IC package 1826 is disposed between the circuit board 1802 and the second IC package 1832. The coupling components 1828, 1830 may take the form of any of the examples of the coupling components 1816 discussed above, and the IC packages 1826, 1832 may take the form of any of the examples of the IC package 1820 discussed above. The package-on-package structure 1834 may be configured in accordance with any of the package-on-package structures known in the art.

FIG. 19 is a block diagram of an example electrical device 1900 that may include one or more of the example 100, 200, 500, 800, 1300. For example, any suitable ones of the components of the electrical device 1900 may include one or more of the device assemblies 1800, IC devices 1700, or dies 1602 disclosed herein, and may be arranged in the example IC packages 100, 200, 500, 800, 1300. A number of components are illustrated in FIG. 19 as included in the electrical device 1900, but any one or more of these components may be omitted or duplicated, as suitable for the application. In some examples, some or all of the components included in the electrical device 1900 may be attached to one or more motherboards. In some examples, some or all of these components are fabricated onto a single system-on-a-chip (SoC) die.

Additionally, in various examples, the electrical device 1900 may not include one or more of the components illustrated in FIG. 19, but the electrical device 1900 may include interface circuitry for coupling to the one or more components. For example, the electrical device 1900 may not include a display 1906, but may include display interface circuitry (e.g., a connector and driver circuitry) to which a display 1906 may be coupled. In another set of examples, the electrical device 1900 may not include an audio input device 1918 (e.g., microphone) or an audio output device 1908 (e.g., a speaker, a headset, earbuds, etc.), but may include audio input or output device interface circuitry (e.g., connectors and supporting circuitry) to which an audio input device 1918 or audio output device 1908 may be coupled.

The electrical device 1900 may include programmable circuitry 1902 (e.g., one or more processing devices). The programmable circuitry 1902 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1900 may include a memory 1904, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1904 may include memory that shares a die with the programmable circuitry 1902. This memory may be used as cache memory and may include embedded dynamic random access memory (eDRAM) or spin transfer torque magnetic random access memory (STT-MRAM).

In some examples, the electrical device 1900 may include a communication chip 1912 (e.g., one or more communication chips). For example, the communication chip 1912 may be configured for managing wireless communications for the transfer of data to and from the electrical device 1900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples the associated devices might not.

The communication chip 1912 may implement any of a number of wireless standards or protocols, including but not limited to Institute of Electrical and Electronics Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. In other examples, the communication chip 1912 may operate in accordance with other wireless protocols. The electrical device 1900 may include an antenna 1922 to facilitate wireless communications and/or to receive other wireless communications (such as AM or FM radio transmissions).

In some examples, the communication chip 1912 may manage wired communications, such as electrical, optical, or any other suitable communication protocols (e.g., the Ethernet). As noted above, the communication chip 1912 may include multiple communication chips. For instance, a first communication chip 1912 may be dedicated to shorter-range wireless communications such as Wi-Fi or Bluetooth, and a second communication chip 1912 may be dedicated to longer-range wireless communications such as global positioning system (GPS), EDGE, GPRS, CDMA, WiMAX, LTE, EV-DO, or others. In some examples, a first communication chip 1912 may be dedicated to wireless communications, and a second communication chip 1912 may be dedicated to wired communications.

The electrical device 1900 may include battery/power circuitry 1914. The battery/power circuitry 1914 may include one or more energy storage devices (e.g., batteries or capacitors) and/or circuitry for coupling components of the electrical device 1900 to an energy source separate from the electrical device 1900 (e.g., AC line power).

The electrical device 1900 may include a display 1906 (or corresponding interface circuitry, as discussed above). The display 1906 may include any visual indicators, such as a heads-up display, a computer monitor, a projector, a touchscreen display, a liquid crystal display (LCD), a light-emitting diode display, or a flat panel display.

The electrical device 1900 may include an audio output device 1908 (or corresponding interface circuitry, as discussed above). The audio output device 1908 may include any device that generates an audible indicator, such as speakers, headsets, or earbuds.

The electrical device 1900 may include an audio input device 1918 (or corresponding interface circuitry, as discussed above). The audio input device 1918 may include any device that generates a signal representative of a sound, such as microphones, microphone arrays, or digital instruments (e.g., instruments having a musical instrument digital interface (MIDI) output).

The electrical device 1900 may include GPS circuitry 1916. The GPS circuitry 1916 may be in communication with a satellite-based system and may receive a location of the electrical device 1900, as known in the art.

The electrical device 1900 may include any other output device 1910 (or corresponding interface circuitry, as discussed above). Examples of the other output device 1910 may include an audio codec, a video codec, a printer, a wired or wireless transmitter for providing information to other devices, or an additional storage device.

The electrical device 1900 may include any other input device 1920 (or corresponding interface circuitry, as discussed above). Examples of the other input device 1920 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1900 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1900 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time +1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, methods, apparatus, and articles of manufacture have been disclosed that improve and/or facilitate semiconductor die efficiency and/or fabrication. Example methods, apparatus, systems, and articles of manufacture to improve interconnect bridge pitch scaling and overlay alignment are disclosed herein. Further examples and combinations thereof include the following:

Example 1 includes an IC package including a package substrate including a cavity, an interconnect bridge positioned in the cavity of the package substrate, the interconnect bridge including one or more pillars, the pillars having a straight-wall profile, a layer of material to encapsulate the pillars, the pillars providing surface pads of first level interconnects, and a die coupled to the pillars of the interconnect bridge.

Example 2 includes the IC package of example 1, wherein the pillars have a substantially uniform diameter along an entire length of the pillars.

Example 3 includes the apparatus of any one or more of examples 1-2, wherein the pillars have a bump pitch that is less than 25 micrometers.

Example 4 includes the IC package of example 3, wherein the bump pitch is less than or equal to 15 micrometers.

Example 5 includes the apparatus of any one or more of examples 1-4, wherein a first pillar of the interconnect bridge is coupled to a first contact pad of the package substrate by a trace provided in the surface metal routing layer.

Example 6 includes the apparatus of any one or more of examples 1-5, wherein the pillars are directly coupled to bridge bumps of the die.

Example 7 includes the apparatus of any one or more of examples 1-6, including a plurality of contact pads, the contact pads coupled to respective ones of the pillars.

Example 8 includes the IC package of example 7, wherein the contact pads have a diameter that is greater than a diameter of the pillars.

Example 9 includes the apparatus of any one or more of examples 7-8, including a trace provided in the layer of material, the trace conductively coupling a first pillar of the interconnect bridge adjacent a second pillar of the interconnect bridge.

Example 10 includes the apparatus of any one or more of examples 1-9, wherein the pillars extend beyond an outer surface of the layer of material.

Example 11 includes the IC package of example 10, including solder at an end of a first one of the pillars without any metal features extending laterally beyond the straight-wall profile of the first pillar and the solder.

Example 12 includes the apparatus of any one or more of examples 1-11, wherein the layer of material includes polyimide.

Example 13 includes the apparatus of any one or more of examples 1-12, including a mold material within the cavity and between the interconnect bridge and the package substrate.

Example 14 includes the apparatus of any one or more of examples 1-13, including a dielectric layer between the pillars of the interconnect bridge.

Example 15 includes an apparatus having a package substrate, a semiconductor die attached to an outer surface of the package substrate, an interconnect bridge embedded within the package substrate, and at least one pillar extending from the interconnect bridge toward the semiconductor die, the pillar having a uniform width along a full length of the pillar from a first end at the interconnect bridge to a second end distal from the interconnect bridge.

Example 16 includes the package substrate of example 15, including a through substrate via (TSV) provided with the interconnect bridge, the TSV to conductively couple conductive contacts between opposing first and second surfaces of the interconnect bridge.

Example 17 includes the apparatus of any one or more of examples 15-16, wherein the pillar extends continuously through the package substrate.

Example 18 includes the apparatus of any one or more of examples 15-17, wherein the pillar extends continuously from the interconnect bridge outside of the outer surface of the package substrate.

Example 19 includes the package substrate of example 18, wherein the pillar has an end that is substantially flush with the outer surface of the package substrate.

Example 20 includes the apparatus of any one or more of examples 18-19, wherein at least a portion of the pillar protrudes from the outer surface of the package substrate.

Example 21 includes the apparatus of any one or more of examples 18-20, including a polymer layer or a solder resist layer providing the outer surface of the package substrate.

Example 22 includes the apparatus of any one or more of examples 15-21, wherein the pillar is a first pillar, and further including a second pillar and a trace, the trace conductively couples the first pillar and the second pillar, the trace provided along a length of the first and second pillars.

Example 23 includes the apparatus of any one or more of examples 15-22, including a mold material in a cavity of the package substrate and between the interconnect bridge and the package substrate.

Example 24 includes an apparatus including an interconnect bridge and at least one pillar extending from the interconnect bridge, the pillar having a uniform width along a full length of the pillar from a first end at the interconnect bridge to a second end distal from the interconnect bridge.

Example 25 includes the apparatus of example 24, wherein the interconnect bridge is to be embedded within a package substrate.

Example 26 includes an apparatus having a package substrate having a cavity, and an interconnect bridge embedded in the cavity of the package substrate, the interconnect bridge including at least one pillar extending from the interconnect bridge, the pillar having a uniform width along a full length of the pillar from a first end at the interconnect bridge to a second end distal from the interconnect bridge.

Example 27 includes the apparatus of example 26, wherein the pillar extends through an outer layer of the package substrate.

Example 28 includes the package substrate of example 26, wherein the pillar extends beyond an outer surface of the package substrate.

Example 29 includes a method including providing a package substrate having a cavity, obtaining an interconnect bridge having pre-formed pillars protruding therefrom, embedding the interconnect bridge in the cavity of the package substrate, providing a dielectric material to surround the pillars, and assembling a die to the pillars of the package substrate.

Example 30 includes the method of example 29, wherein assembling the die includes directly coupling the die and the pillars via hybrid bonding.

Example 31 includes the method of any one or more of examples 29-30, including providing a surface metal routing layer that includes one or more vias and traces using a dual damascene process.

Example 32 includes Th method of example 29, including providing a trace to couple two adjacent pillars.

Example 33 includes the method of any one or more of examples 29-32, including employing a masked dry etching process to provide a trench and cavities and filling the trench and cavities with conductive material via electroplating.

Example 34 includes the method of any one or more of examples 29-33, including etching the dielectric material to expose sidewalls of at least a portion of the pillars.

Example 35 includes the method of any one or more of examples 29-34, including etching the dielectric material to expose the pillars and providing solder on ends of the pillars.

Example 36 includes the method of any one or more of examples 29-35, including forming a surface metal routing layer without using any drilling processes.

Example 37 includes the method of any one or more of examples 29-36, including providing a mold material within the cavity and between the interconnect bridge and the package substrate.

Example 38 includes a method including providing a package substrate with a cavity, providing an interconnect bridge having bridge pads, positioning the interconnect bridge in the cavity, providing pillars in alignment with respective ones of the bridge pads via photolithography, the pillars having a uniform diameter along a length of the pillars, the pillars conductively coupled to respective ones of the bridge pads, and encapsulating the pillars via a molding process to encase the pillars.

Example 39 includes the method of example 38, wherein the pillars are first pillars, the method including patterning cavities in alignment with the first pillars via photolithography.

Example 40 includes the method of example 39, including adding conductive material in the cavities via an electroplating process to provide contact pads conductively coupled to respective ones of the first pillars, the contact pads each having a diameter that is greater than a diameter of the first pillars.

Example 41 includes the method of example 40, including providing second pillars in alignment with the contact pads via lithography, the second pillars conductively coupled to respective ones of the contact pads.

Example 42 includes the method of example 41, including providing a die encapsulation mold layer to encase the second pillars.

Example 43 includes the method of example 42, including providing bump pads on the die encapsulation mold layer via lithography, the bump pads conductively coupled to respective ones of the second pillars.

Example 44 includes the method of example 43, including providing solder on the bump pads.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An IC package comprising:
a package substrate including a cavity;
an interconnect bridge positioned in the cavity of the package substrate, the interconnect bridge including one or more pillars, the pillars having a straight-wall profile;
a layer of material to encapsulate the pillars, the pillars providing at least a portion of a surface metal routing layer; and
a die coupled to the pillars of the interconnect bridge.

2. The IC package of claim 1, wherein the pillars have a substantially uniform diameter along an entire length of the pillars.

3. The IC package of claim 1, wherein the pillars have a bump pitch that is less than 25 micrometers.

4. (canceled)

5. The IC package of claim 1, wherein a first pillar of the interconnect bridge is coupled to a first contact pad of the package substrate by a trace provided in the surface metal routing layer.

6. The IC package of claim 1, wherein the pillars are directly coupled to bridge bumps of the die.

7. The IC package of claim 1, including a plurality of contact pads, the contact pads coupled to respective ones of the pillars.

8. The IC package of claim 7, wherein the contact pads have a diameter that is greater than a diameter of the pillars.

9. The IC package of claim 7, including a trace provided in the layer of material, the trace conductively coupling a first pillar of the interconnect bridge adjacent a second pillar of the interconnect bridge.

10. The IC package of claim 1, wherein the pillars extend beyond an outer surface of the layer of material.

11. (canceled)

12. The IC package of claim 1, wherein the layer of material includes polyimide.

13. The IC package of claim 1, including a mold material within the cavity and between the interconnect bridge and the package substrate.

14. The IC package of claim 1, including a dielectric layer between the pillars of the interconnect bridge.

15. An apparatus comprising:
a package substrate;
a semiconductor die attached to an outer surface of the package substrate;
an interconnect bridge embedded within the package substrate; and
at least one pillar extending from the interconnect bridge toward the semiconductor die, the pillar having a uniform width along a full length of the pillar from a first end at the interconnect bridge to a second end distal from the interconnect bridge.

16. (canceled)

17. (canceled)

18. (canceled)

19. The package substrate of claim 15, wherein the pillar has an end that is substantially flush with an outer surface of the package substrate.

20. The package substrate of claim 15, wherein at least a portion of the pillar protrudes from an outer surface of the package substrate.

21. The package substrate of claim 15, including a polymer layer or a solder resist layer providing an outer surface of the package substrate.

22. The package substrate of claim 15, wherein the pillar is a first pillar, and including a second pillar and a trace, the trace conductively coupled to the first pillar and the second pillar, the trace provided along a length of the first and second pillars.

23. The package substrate of claim 15, including a mold material in a cavity of the package substrate and between the interconnect bridge and the package substrate.

24. An apparatus comprising:
an interconnect bridge; and
at least one pillar extending from the interconnect bridge, the pillar having a uniform width along a full length of the pillar from a first end at the interconnect bridge to a second end distal from the interconnect bridge.

25. The apparatus of claim 24, wherein the interconnect bridge is to be embedded within a package substrate.

26.-44. (canceled).
